(19) United States
(12) Patent Application Publication
(10) Pub. No.: US 2016/0149091 A1
(43) Pub. Date: May 26, 2016

(54) LIGHT-EMITTING MATERIAL, METHOD FOR PRODUCING SAME, OPTICAL FILM, AND LIGHT-EMITTING DEVICE

(71) Applicant: KONICA MINOLTA, INC., Tokyo (JP)

(72) Inventor: Maiko KONDO, Hino-shi, Tokyo (JP)

(21) Appl. No.: 14/901,323

(22) PCT Filed: Jun. 23, 2014
(86) PCT No.: PCT/JP2014/066503

§ 371 Date: Dec. 28, 2015

(30) Foreign Application Priority Data
Jun. 25, 2013 (JP) 2013-132434

(51) Int. Cl. H01L 33/50; C09K 11/88; C09K 11/70

(52) U.S. Cl. CPC H01L 33/502; C09K 11/703; C09K 11/883

(57) ABSTRACT

The purpose of the invention is to provide a high-transparency light-emitting material of sufficient durability to minimize long-term degradation of semiconductor nanoparticles due to oxygen, etc.; and a method for producing said material. This light-emitting material is characterized in containing semiconductor nanoparticles, a metal alkoxide, and a silicon compound.

### TECHNICAL FIELD

The present invention relates to a luminous material, a method for producing the luminous material, an optical film, and a light-emitting device. In specific, the present invention relates to a luminous material having high transparency and high durability such that semiconductor nanoparticles contained in the luminous material are prevented from being degraded by oxygen for a long period of time.

### BACKGROUND ART

In recent years, semiconductor nanoparticles (quantum dots) have received commercial attention because of their size-tunable electronic properties. Semiconductor nanoparticles are a promising material for various applications, such as biological labeling, photovoltaics, catalysis, biological imaging, light-emitting diodes (LEDs), common space lighting, and electroluminescent displays.

In a proposed technique for using semiconductor nanoparticles in a light-emitting device, the semiconductor nanoparticles are irradiated with light from an LED, to increase the intensity of light incident on a liquid crystal display (LCD) for enhancing the luminance of the LCD (see, for example, PTL 1).

Various techniques have been disclosed for preventing semiconductor nanoparticles from coming into contact with oxygen, which degrades the semiconductor nanoparticles. Such a technique involves, for example, covering semiconductor nanoparticles with a barrier film or a covering material. Although such a technique secures oxygen barrier properties, the technique requires expensive and sophisticated production equipment (e.g., requirement of a covering process in an N₂ atmosphere); i.e., the technique lacks versatility.

In contrast, techniques have been proposed for coating semiconductor nanoparticles with silica or glass, to prevent the nanoparticles from coming into contact with oxygen (see, for example, PTLs 2 and 3).

Unfortunately, such a conventional coating technique encounters difficulty in evenly coating semiconductor nanoparticles with silica or glass, resulting in generation of portions having poor oxygen barrier properties. Thus, the coating technique causes degradation of the semiconductor nanoparticles due to contact with oxygen, leading to a reduction in luminance and insufficient emission efficiency. The coating technique may form silica aggregates of large size, leading to poor dispersibility of the nanoparticles in a resin and low transparency of the resultant luminous material. The luminous material may be affected by the external environment, resulting in poor oxygen barrier properties and a reduction in luminance; i.e., the luminous material has unsatisfactory transparency and durability.

### PRIOR ART DOCUMENTS

### Patent Documents

### PTL 1: Japanese Unexamined Patent Application Publication No. 2011-202148

### PTL 2: International Patent Publication WO2007/034877

### PTL 3: Japanese Translation of PCT International Application Publication No. 2013-505347

### DISCLOSURE OF THE INVENTION

### Problems to be Solved by the Invention

The present invention has been attained in consideration of the problems and circumstances described above. Objects of the present invention are to provide a luminous material having high transparency and high durability such that semiconductor nanoparticles contained in the luminous material are prevented from being degraded by oxygen for a long period of time, a method for producing the luminous material, an optical film containing the luminous material, and a light-emitting device including the optical film.

### Means for Solving the Problem

The present inventor, who has conducted studies to solve the problems described above, has found that a luminous material containing semiconductor nanoparticles, a metal alkoxide, and a silicon compound has high transparency and high durability such that the semiconductor nanoparticles are prevented from being degraded by oxygen for a long period of time.

The present invention to solve the problems described above is characterized by the following aspects:

1. A luminous material including: a semiconductor nanoparticle; a metal alkoxide; and a silicon compound.

2. The luminous material described in the aspect 1, wherein metal of the metal alkoxide includes at least one of boron (B), magnesium (Mg), aluminum (Al), calcium (Ca), titanium (Ti), iron (Fe), zinc (Zn), gallium (Ga), zirconium (Zr), indium (In) and rhodium (Rh).

3. The luminous material described in the aspect 1 or 2, wherein the silicon compound is at least one of a polysilazane and a modified polysilazane.

4. The luminous material described in any one of the aspects 1 to 3, wherein the semiconductor nanoparticle is coated with the silicon compound.

5. The luminous material described in any one of the aspects 1 to 4, wherein the silicon compound is modified.

6. A method for producing the luminous material described in anyone of the aspects 1 to 5, including: preparing a mixture of the metal alkoxide and the silicon compound; and reacting the mixture with the semiconductor nanoparticle, to coat the semiconductor nanoparticle with silica.

7. An optical film including a semiconductor nanoparticulate layer comprising the luminous material described in any one of the aspects 1 to 5.

8. A light-emitting device including the optical film described in the aspect 7.

### Effects of the Invention

The present invention can provide a luminous material having high transparency and high durability such that semiconductor nanoparticles contained in the luminous material are prevented from being degraded by oxygen for a long period of time, and a method for producing the luminous material. The present invention can also provide an optical film and a light-emitting device, each of which contains the luminous material.

The mechanism by which the advantageous effects of the present invention are achieved has not yet been elucidated, but is presumed as described below.

In order to solve the aforementioned problems, the present inventor has conducted extensive studies and has found that a luminous material containing semiconductor nanoparticles, a metal alkoxide, and a silicon compound exhibits high transparency and durability. The possible mechanism for this phenomenon is proposed as follows. The semiconductor nanoparticles are coated with the metal alkoxide through interaction between surface functional groups of the nanoparticles and alkoxy groups of metal alkoxide molecules. Because metal ions of the metal alkoxide molecules coordinate to silicon atoms of the silicon compound, the surfaces of the semiconductor nanoparticles can be uniformly coated with the silicon compound. Thus, formation of the coating layer having high gas barrier properties significantly improves the oxygen barrier properties.

According to the present invention, the semiconductor nanoparticles can be uniformly coated with the silicon compound, and thus silica aggregates of large size are less likely to be formed, resulting in improved dispersibility of the semiconductor nanoparticles in a resin, and high transparency of the luminous material.

### BRIEF DESCRIPTION OF DRAWINGS

FIG. 1 A schematic cross-sectional view of a display including an optical film according to an embodiment of the present invention.

### EMBODIMENTS FOR CARRYING OUT THE INVENTION

The luminous material of the present invention contains semiconductor nanoparticles, a metal alkoxide, and a silicon compound. This technical feature is common to Aspects 1 to 8 of the present invention.

In a preferred embodiment of the present invention, from a viewpoint of advantageous effects of the present invention, the metal of the metal alkoxide is at least one of boron (B), magnesium (Mg), aluminum (Al), calcium (Ca), titanium (Ti), iron (Fe), zinc (Zn), gallium (Ga), zirconium (Zr), indium (In), and rhodium (Rh). More preferably, the silicon compound is a polysilazane or a modified polysilazane in view of uniform coating of the semiconductor nanoparticles with silica.

In a preferred embodiment, the semiconductor nanoparticles are coated with the silicon compound. The silicon compound is preferably modified in view of formation of a transparent, homogeneous glass layer and achievement of high oxygen barrier properties.

The method for producing a luminous material of the present invention preferably comprises preparing a mixture of a metal alkoxide and a silicon compound, and reacting the mixture with semiconductor nanoparticles, to coat the semiconductor nanoparticles with silica. The method can uniformly coat the semiconductor nanoparticles with silica.

The luminous material of the present invention can be used for forming an optical film including a semiconductor nanoparticulate layer. The optical film is suitable for use in a light-emitting device.

The present invention, the contexture thereof, and embodiments and aspects for implementing the present invention will now be described in detail. As used herein, the term to between two numerical values indicates that the numeric values before and after the term are inclusive as the lower limit value and the upper limit value, respectively.

<<Luminous Material of the Present Invention>>

The present invention provides a luminous material containing semiconductor nanoparticles, a metal alkoxide, and a silicon compound, the luminous material having high transparency and high durability such that the semiconductor nanoparticles are prevented from being degraded by oxygen for a long period of time. The present invention also provides a method for producing the luminous material.

The semiconductor nanoparticles are prepared into a coating liquid for formation of a semiconductor nanoparticulate layer, and the coating liquid is then applied to a substrate, to form an optical film including a semiconductor nanoparticulate layer. The optical film is suitable for use in a light-emitting device.

<<Components of Luminous Material of the Present Invention>>

<<Semiconductor Nanoparticles>>

In the present invention, the semiconductor nanoparticles are fine particles composed of semiconductor crystals and having a quantum confinement effect; specifically, fine particles having a particle size of several nanometers to several tens of nanometers and having a quantum dot effect described below.

In the present invention, the semiconductor nanoparticles preferably have a particle size of 1 to 20 nm, more preferably 1 to 10 nm.

The energy level E of such a semiconductor nanoparticle is represented by Expression (1):

E∝h²/mR2 Expression (1):

where h represents Planck's constant, m represents electron effective mass, and R represents the radius of the semiconductor nanoparticle.

As shown by Expression (1), the band gap of a semiconductor nanoparticle increases proportional to “R⁻²,” resulting in a quantum dot effect. Thus, the band gap of a semiconductor nanoparticle can be controlled by regulating the particle size thereof. Semiconductor nanoparticles having a regulated particle size exhibit various properties that are not generally observed in atoms; specifically, the nanoparticles are excited by light, and the nanoparticles emit light having a desired wavelength. As used herein, the term “semiconductor nanoparticles” refers to such a luminous semiconductor nanoparticulate material.

As described above, the semiconductor nanoparticles have a mean particle size of about several nanometers to several tens of nanometers. The mean particle size is adjusted depending on the target color of light to be emitted. For example, the mean particle size of the semiconductor nanoparticles is preferably adjusted to 3.0 to 20 nm for emission of red light, 1.5 to 10 nm for emission of green light, and 1.0 to 3.0 nm for emission of blue light.

The mean particle size may be determined by a known process. For example, the number average particle size of semiconductor nanoparticles may be determined on the basis of the particle size distribution of the nanoparticles observed with a transmission electron microscope (TEM). Alternatively, the mean particle size may be determined with an atomic force microscope (AFM) or a particle size meter based on dynamic light scattering, such as “ZETASIZERNano Series Nano-ZS” manufactured by Malvern. Alternatively, the particle size distribution of semiconductor nanoparticles may be determined through simulation on the basis of a spectrum of the nanoparticles obtained by small angle X-ray scattering. In the present invention, the mean particle size is preferably determined with an atomic force microscope (AFM).

In the present invention, the semiconductor nanoparticles preferably have an aspect ratio (major-axis size/minor-axis size) of 1.0 to 2.0, more preferably 1.1 to 1.7. In the present invention, the aspect ratio (major-axis size/minor-axis size) of the semiconductor nanoparticles may be determined with an atomic force microscope (AFM). Preferably, 300 or more semiconductor nanoparticles are subjected to determination of the aspect ratio.

The amount of the semiconductor nanoparticles is preferably 0.01 to 50 mass %, more preferably 0.5 to 30 mass %, most preferably 2.0 to 25 mass %, relative to 100 mass % of the total amount of the components of the semiconductor nanoparticulate layer. An amount of 0.01 mass % or more leads to sufficient emission efficiency, whereas an amount of 50 mass % or less leads to an appropriate distance between semiconductor nanoparticles, resulting in a significant quantum size effect.

(1) Material for Semiconductor Nanoparticles

Examples of the material for the semiconductor nanoparticles include elements belonging to Group 14 of the periodic table, such as carbon, silicon, germanium, and tin; elements belonging to Group 15 of the periodic table, such as phosphorus (black phosphorus); elements belonging to Group 16 of the periodic table, such as selenium and tellurium; compounds composed of two or more elements belonging to Group 14 of the periodic table, such as silicon carbide (SiC); compounds composed of elements belonging to Groups 14 and 16 of the periodic table, such as tin (IV) oxide (SnO₂), tin (II, IV) sulfide (Sn(II)Sn(IV)S₃), tin (IV) sulfide (SnS₂), tin (II) sulfide (SnS), tin (II) selenide (SnSe), tin (II) telluride (SnTe), lead (II) sulfide (PbS), lead (II) selenide (PbSe), and lead (II) telluride (PbTe); compounds composed of elements belonging to Groups 13 and 15 of the periodic table (or Group III-V compound semiconductors), such as boron nitride (BN), boron phosphide (BP), boron arsenide (BAs), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), and indium antimonide (InSb); compounds composed of elements belonging to Groups 13 and 16 of the periodic table, such as aluminum sulfide (Al₂S₃), aluminum selenide (Al₂Se₃), gallium sulfide (Ga₂S₃), gallium selenide (Ga₂Se₃), gallium telluride (Ga₂Te₃), indium oxide (In₂O₃), indium sulfide (In₂S₃), indium selenide (In₂Se₃), and indium telluride (In₂Te₃); compounds composed of elements belonging to Groups 13 and 17 of the periodic table, such as thallium (I) chloride (TlCl) thallium (I) bromide (TlBr), and thallium (I) iodide (TlI), compounds composed of elements belonging to Groups 12 and 16 of the periodic table (or Group II-VI compound semiconductors), such as zinc oxide (ZnO), zinc sulfide (ZnS), zinc selenide (ZnSe), zinc telluride (ZnTe), cadmium oxide (CdO), cadmium sulfide (CdS), cadmium selenide (CdSe), cadmium telluride (CdTe), mercury sulfide (HgS), mercury selenide (HgSe), and mercury telluride (HgTe); compounds composed of elements belonging to Groups 15 and 16 of the periodic table, such as arsenic (III) sulfide (As₂S₃), arsenic (III) selenide (As₂Se₃), arsenic (III) telluride (As₂Te₃), antimony (III) sulfide (Sb₂S₃), antimony (III) selenide (Sb₂Se₃), antimony (III) telluride (Sb₂Te₃), bismuth (III) sulfide (Bi₂S₃), bismuth (III) selenide (Bi₂Se₃), and bismuth (III) telluride (Bi₂Te₃); compounds composed of elements belonging to Groups 11 and 16 of the periodic table, such as copper (I) oxide (Cu₂O) and copper (I) selenide (Cu₂Se); compounds composed of elements belonging to Groups 11 and 17 of the periodic table, such as copper (I) chloride (CuCl), copper (I) bromide (CuBr), copper (I) iodide (CuI), silver chloride (AgCl), and silver bromide (AgBr); compounds composed of elements belonging to Groups 10 and 16 of the periodic table, such as nickel (II) oxide (NiO); compounds composed of elements belonging to Groups 9 and 16 of the periodic table, such as cobalt (II) oxide (CoO) and cobalt (II) sulfide (CoS); compounds composed of elements belonging to Groups 8 and 16 of the periodic table, such as triiron tetraoxide (Fe₃O₄) and iron (II) sulfide (FeS); compounds composed of elements belonging to Groups 7 and 16 of the periodic table, such as manganese (II) oxide (MnO); compounds composed of elements belonging to Groups 6 and 16 of the periodic table, such as molybdenum (IV) sulfide (MoS₂) and tungsten (IV) oxide (WO₂); compounds composed of elements belonging to Groups 5 and 16 of the periodic table, such as vanadium (II) oxide (VO), vanadium (IV) oxide (VO₂), and tantalum (V) oxide (Ta₂O₅); compounds composed of elements belonging to Groups 4 and 16 of the periodic table, such as titanium oxides (e.g., TiO₂, Ti₂O₅, Ti₂O₃, and Ti₅O₉); compounds composed of elements belonging to Groups 2 and 16 of the periodic table, such as magnesium sulfide (MgS) and magnesium selenide (MgSe); chalcogenide spinels, such as cadmium (II) chromium (III) oxide (CdCr₂O₄), cadmium (II) chromium (III) selenide (CdCr₂Se₄), copper (II) chromium (III) sulfide (CuCr₂S₄), and mercury (II) chromium (III) selenide (HgCr₂Se₄); and barium titanate (BaTiO₃). Preferred are compounds composed of elements belonging to Groups 14 and 16 of the periodic table, such as SnS₂, SnS, SnSe, SnTe, PbS, PbSe, and PbTe; Group III-V compound semiconductors, such as GaN, GaP, GaAs, GaSb, InN, InP, InAs, and InSb; compounds composed of elements belonging to Groups 13 and 16 of the periodic table, such as Ga₂O₃, Ga₂S₃, Ga₂Se₃, Ga₂Te₃, In₂O₃, In₂S₃, In₂Se₃, and In₂Te₃; Group II-VI compound semiconductors, such as ZnO, ZnS, ZnSe, ZnTe, CdO, CdS, CdSe, CdTe, HgO, HgS, HgSe, and HgTe; compounds composed of elements belonging to Groups 15 and 16 of the periodic table, such as As₂O₃, As₂S₃, As₂Se₃, As₂Te₃, Sb₂O₃, Sb₂S₃, Sb₂Se₃, Sb₂Te₃, Bi₂O₃, Bi₂S₃, Bi₂Se₃, and Bi₂Te₃; and compounds composed of elements belonging to Groups 2 and 16 of the periodic table, such as MgS and MgSe. More preferred are Si, Ge, GaN, GaP, InN, InP, Ga₂O₃, Ga₂S₃, In₂O₃, In₂S₃, ZnO, ZnS, CdO, and CdS. These materials, which do not contain a highly toxic negative element, cause no environmental pollution and exhibit high safety to organisms. These materials exhibit clear spectra in a visible light region, and thus are advantageously used for the production of light-emitting devices. Of these materials, CdSe, ZnSe, and CdS are preferred in view of reliable emission of light. ZnO or ZnS semiconductor nanoparticles are preferably used in view of emission efficiency, high refractive index, safety, and cost. The aforementioned materials may be used alone or in combination.

The semiconductor nanoparticles may optionally be doped with a small amount of any element serving as an impurity. Addition of such a dopant can significantly improve emission characteristics.

As used herein, the band gap (eV) of the semiconductor nanoparticles (i.e., an inorganic material) corresponds to the difference in energy level between the valence and conduction bands of the inorganic material. The emission wavelength (nm) of the nanoparticles is determined by the following expression: 1240/band gap (eV).

The band gap (eV) of the semiconductor nanoparticles can be determined by the Tauc plot method.

Now will be described the Tauc plot method, which is a photochemical technique for determining the band gap (eV).

Specifically, a band gap energy (E₀) is determined by the Tauc plot as follows:

In a highly absorptive region at the long-wavelength optical absorption edge of a semiconductor material, the following Expression (A) is satisfied:

αhν=B(hν−E₀)² Expression (A):

where a represents optical absorption coefficient, hν represents optical energy (h: Planck's constant, ν: frequency), and E₀ represents band gap energy.

Specifically, the absorption spectrum of semiconductor nanoparticles is measured, the optical energy hν is plotted against (αhν)^{0.5} (i.e., Tauc plotting), and then the resultant straight-line segment is extrapolated. The hν value at α=0 corresponds to the band gap energy E₀ of the semiconductor nanoparticles.

The semiconductor nanoparticles exhibit sharp absorption and emission spectra and a small Stokes shift. Thus, the maximum wavelength of the emission spectrum may be used as an index of the band gap for the sake of convenience.

The band gap of such an organic or inorganic functional material may be calculated on the basis of the energy level of the material determined by scanning tunneling spectroscopy, ultraviolet photoelectron spectroscopy, X-ray photoelectron spectroscopy, or Auger electron spectroscopy. Alternatively, the band gap may be determined by any optical technique.

In the present invention, the surface of a semiconductor nanoparticle (core) is preferably provided with a shell layer; i.e., an inorganic coating layer or a layer composed of an organic ligand and a metal alkoxide. More preferably, the shell layer is coated with a silicon compound.

The core-shell structure is preferably composed of at least two compounds. The core-shell structure may have a gradient structure composed of two or more compounds. This core-shell structure can effectively prevent aggregation of semiconductor nanoparticles in a coating liquid for formation of a semiconductor nanoparticulate layer, and can improve the dispersibility of the nanoparticles in the coating liquid, resulting in high emission efficiency. Thus, even if a light-emitting device including the optical film of the present invention is continuously operated, color drift can be prevented. The presence of the coating layer provides consistent emission characteristics.

If the surface of a semiconductor nanoparticle is coated with the shell layer, a surface modifier described below can be certainly supported around the surface of semiconductor nanoparticle.

The shell layer may have any thickness, but preferably has a thickness of 0.1 to 10 nm, more preferably 0.1 to 5 nm.

In general, the color of light to be emitted can be controlled by regulating the mean particle size of the semiconductor nanoparticles. If the coating layer has a thickness within the above range (i.e., a thickness corresponding to the size of several atoms to a thickness below the size of one semiconductor nanoparticle), the semiconductor nanoparticles can be dispersed at a high density, resulting in a sufficient emission intensity. The presence of the coating layer precludes non-luminous electronic energy transfer due to trapping of electrons by dangling bonds (defects) on the surface of a core particle, thereby preventing a reduction in quantum efficiency.

In the present invention, the semiconductor nanoparticles preferably have a means particle size of 1 to 20 nm as described above. As used herein, the size of a semiconductor nanoparticle corresponds to the overall size of the core-shell structure including the core composed of the material of the semiconductor nanoparticle, the shell layer, and the surface modifier. If neither the shell layer nor the surface modifier is present, the size of a semiconductor nanoparticle corresponds to that of the core.

(2) Production of Semiconductor Nanoparticles

The semiconductor nanoparticles may be produced by any traditional process. The semiconductor nanoparticles are commercially available from, for example, Aldrich, Crystalplex, and NNLab.

The semiconductor nanoparticles may be produced by a high-vacuum process, such as molecular beam epitaxy or CVD. Alternatively, the semiconductor nanoparticles may be produced by a liquid-phase process; for example, a reverse micelle process in which an aqueous raw material solution is provided in the form of reverse micelles in a non-polar organic solvent, such as an alkane (e.g., n-heptane, n-octane, or isooctane) or an aromatic hydrocarbon (e.g., benzene, toluene, or xylene), and crystals are grown in the reverse micelle phase; a hot soap process in which a thermally degradable raw material is injected into an organic liquid medium at a high temperature for growth of crystals; or a solution reaction process in which crystals are grown at a relatively low temperature through acid-base reaction similar to the case of a hot soap process. The semiconductor nanoparticles may be produced by any of these processes. In particular, a liquid-phase process is preferred.

In the synthesis of semiconductor nanoparticles by a liquid-phase process, the organic surface modifier on the surfaces of the nanoparticles is called an initial surface modifier. Examples of the initial surface modifier used in a hot soap process include trialkylphosphines, trialkylphosphine oxides, alkylamines, dialkyl sulfoxides, and alkanephosphonic acids. Such an initial surface modifier is preferably replaced with a functional surface modifier described below by an exchange reaction. Specifically, the initial surface modifier used in the aforementioned hot soap process (e.g., trioctylphosphine oxide) may be replaced with a functional surface modifier described below by an exchange reaction in a liquid phase containing the functional surface modifier.

<<Metal Alkoxide>>

As used herein, the term “metal alkoxide” refers to a compound composed of a metal element and at least one alkoxy group bonded to the metal element. The metal alkoxide is represented by Formula (M):

M(OR₁)ₐ(R₂)_{b} Formula (M):

where M represents a metal belonging to Groups 1 to 14 of the periodic table or boron; R₁ represents an alkyl group, a cycloalkyl group, an aromatic hydrocarbon group, or a non-aromatic hydrocarbon group; R₂ represents a substituent other than an alkoxy group; a is an integer of 1 or more; b is an integer of 0 or more; and a+b is any number determined by M.

M is a metal belonging to Groups 1 to 14 of the periodic table or boron. In the present invention, M is not a metalloid, such as silicon, germanium, or arsenic. Examples of the metal belonging to Groups 1 to 14 of the periodic table include beryllium (Be), magnesium (Mg), aluminum (Al), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), iridium (Ir), platinum (Pt), gold (Au), mercury (Hg), thallium (Tl), lead (Pb), and radium (Ra).

In particular, M is preferably boron (B), magnesium (Mg), aluminum (Al), calcium (Ca), titanium (Ti), iron (Fe), zinc (Zn), gallium (Ga), zirconium (Zr), indium (In), or rhodium (Rh), more preferably boron (B), magnesium (Mg), aluminum (Al), or iron (Fe).

R₂ may be any substituent other than an alkoxy group. Examples of the substituent include an alkyl group, a cycloalkyl group, an aromatic hydrocarbon group, a non-aromatic hydrocarbon group, an amino group, a halogen atom, a cyano group, a nitro group, a mercapto group, an epoxy group, a hydroxy group, a vinyl group, and an acetylacetonate group. Examples of the alkyl group include linear, branched, and cyclic alkyl groups having one to eight carbon atoms. Specific examples include methyl, ethyl, n-propyl, isopropyl, n-butyl, isobutyl, sec-butyl, tert-butyl, n-pentyl, isopentyl, neopentyl, n-hexyl, n-heptyl, n-octyl, 2-ethylhexyl, cyclopropyl, cyclopentyl, and cyclohexyl. Examples of the aryl group include aryl groups having 6 to 30 carbon atoms. Specific examples include non-condensed hydrocarbon groups, such as phenyl, biphenyl, and terphenyl; and condensed polycyclic hydrocarbon groups, such as pentalenyl, indenyl, naphthyl, azulenyl, heptalenyl, biphenylenyl, fluorenyl, acenaphthylenyl, pleiadenyl, acenaphthenyl, phenalenyl, phenanthryl, anthryl, fluoranthenyl, acephenanthrylenyl, aceanthrylenyl, triphenylenyl, pyrenyl, chrysenyl, and naphthacenyl.

At least one of R₁ and R₂ is preferably an alkyl group having three or more carbon atoms, more preferably a linear alkyl group having three or more carbon atoms. A long-chain metal alkoxide may be synthesized by, for example, the method described in Japanese Unexamined Patent Application Publication No. H09-59192 (Kawaken Fine Chemicals Co., Ltd.).

Examples of the metal alkoxide include trimethyl borate, triethyl borate, tri-n-propyl borate, triisopropyl borate, tri-n-butyl borate, tri-tert-butyl borate, magnesium ethoxide, magnesium ethoxyethoxide, magnesium methoxyethoxide, aluminum trimethoxide, aluminum triethoxide, aluminum tri-n-propoxide, aluminum triisopropoxide, aluminum tri-n-butoxide, aluminum tri-sec-butoxide, aluminum tri-tert-butoxide, acetoalkoxyaluminum diisopropylate, aluminum ethylacetoacetate di-n-butylate, aluminum diethylacetoacetate mono-n-butylate, aluminum diisopropylate mono-sec-butylate, ethylacetoacetate aluminum di-n-butylate, diisopropoxy aluminum acetoacetate, aluminum alkylacetoacetate diisopropylate, aluminum oxide isopropoxide trimer, aluminum oxide octylate trimer, calcium methoxide, calcium ethoxide, calcium isopropoxide, calcium acetylacetonate, scandium acetylacetonate, titanium tetramethoxide, titanium tetraethoxide, titanium tetra-n-propoxide, titanium tetraisopropoxide, titanium tetra-n-butoxide, titanium tetraisobutoxide, titanium diisopropoxy-di-n-butoxide, titanium di-tert-butoxydiisopropoxide, titanium tetra-tert-butoxide, titanium tetraisooctyloxide, titanium tetrastearylalkoxide, vanadium triisobutoxide oxide, chromium n-propoxide, chromium isopropoxide, manganese methoxide, iron methoxide, iron ethoxide, iron n-propoxide, iron isopropoxide, tris(2,4-pentanedionato)iron, cobalt isopropoxide, copper methoxide, copper ethoxide, copper isopropoxide, copper acetylacetonate, zinc ethoxide, zinc ethoxyethoxide, zinc methoxyethoxide, gallium methoxide, gallium ethoxide, gallium isopropoxide, strontium isopropoxide, yttrium n-propoxide, yttrium isopropoxide, zirconium ethoxide, zirconium n-propoxide, zirconium isopropoxide, zirconium butoxide, zirconium tert-butoxide, niobium ethoxide, niobium n-butoxide, niobium tert-butoxide, molybdenum ethoxide, indium isopropoxide, indium isopropoxide, indium n-butoxide, indium methoxyethoxide, tin n-butoxide, tin tert-butoxide, barium diisopropoxide, barium tert-butoxide, lanthanum isopropoxide, lanthanum methoxyethoxide, cerium n-butoxide, cerium tert-butoxide, cerium acetylacetonate, praseodymium methoxyethoxide, neodymium methoxyethoxide, neodymium methoxyethoxide, samarium isopropoxide, hafnium ethoxide, hafnium n-butoxide, hafnium tert-butoxide, tantalum methoxide, tantalum ethoxide, tantalum n-butoxide, tantalum butoxide, tantalum tetramethoxide acetylacetonate, tungsten ethoxide, and thallium ethoxide.

Of these metal alkoxides, preferred are aluminum triisopropoxide, copper isopropoxide, iron isopropoxide, aluminum tri-n-butoxide, aluminum butoxide, aluminum tri-sec-butoxide, aluminum ethylacetoacetate diisopropylate, aluminum diisopropylate mono-sec-butylate, tridodecyloxyaluminum, triisopropyl borate, magnesium n-propoxide, titanium tetrastearylalkoxide, calcium isopropoxide, zinc tert-butoxide, gallium isopropoxide, zirconium isopropoxide, and indium isopropoxide. More preferred are aluminum triisopropoxide, aluminum tri-n-butoxide, aluminum butoxide, aluminum diisopropylate mono-sec-butylate, and tridodecyloxyaluminum.

These metal alkoxides are preferred because they have appropriate reactivity and allow a reliable coating process to be performed under a wide range of conditions.

The mass ratio of the metal alkoxide to the inorganic component of the semiconductor nanoparticles is about 100:1 to 2:1, preferably about 20:1 to 4:1.

The reaction between the metal alkoxide and the semiconductor nanoparticles may be performed at any temperature. The reaction temperature is typically 5 to 50° C., preferably 10 to 40° C. The mixture may be agitated for any period of time. The agitation time is typically one to six hours, preferably two to four hours. Under such conditions, functional groups on the surfaces of the semiconductor nanoparticles interact with alkoxy groups of metal alkoxide molecules, whereby the surfaces of the semiconductor nanoparticles are coated with the metal alkoxide.

<<Silicon Compound>>

The silicon compound used in the present invention may be a siloxane oligomer, a silsesquioxane, a silane alkoxide, a polysilazane, or a modified polysilazane.

(1) Siloxane Oligomer

The siloxane oligomer is a compound having two or more (—Si—O) bonds, and is represented by Formula (S):

[F1]

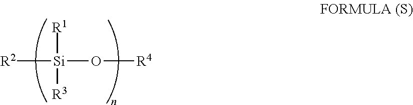

Examples of the substituents represented by R¹, R², R³, and R⁴ include alkyl groups, cycloalkyl groups, alkenyl groups, alkoxy groups, alkynyl groups, aromatic hydrocarbon groups, non-aromatic hydrocarbon groups, an amino group, halogen atoms, a cyano group, a nitro group, a mercapto group, an epoxy group, and a hydroxy group. In Formula (S), n is an integer of 2 or more. Specific examples of the siloxane oligomer include X-40-2308, X-40-9238, X-40-9225, X-40-9227, X-40-9246, KR-500, and KR-510 (manufactured by Shin-Etsu Chemical Co., Ltd.).

(2) Silsesquioxane

The silsesquioxane, which is also called “T resin,” is a siloxane compound having a main structure composed of Si—O bonds. The silsesquioxane (also referred to as “polysilsesquioxane”) is represented by the formula [RSiO_{1.5}], although silica is commonly represented by the formula [SiG₂]. The silsesquioxane is typically a polysiloxane synthesized through hydrolysis and polycondensation of a (RSi(OR′)₃) compound prepared by substitution of an alkyl or aryl group for one alkoxy group of a tetraalkoxysilane (Si(OR′)₄) (e.g., tetraethoxysilane). The silsesquioxane typically has an amorphous, ladder-shaped, or cage-shaped (completely condensed cage) molecular structure. Specific examples of the silsesquioxane include SR2400, SR2402, SR2405, and FOX14 (manufactured by Dow Corning Toray Co., Ltd.), and SST-H8H01 (manufactured by Gelest).

(3) Silane Alkoxide

The silane alkoxide may be a compound represented by Formula (SA):

[F2]

(R⁵O)ₘ—Si—(R⁶)₄₋ₘ FORMULA (SA)

In Formula (SA), m is 1 to 4, preferably 2 to 4, more preferably 3 or 4.

In Formula (SA), R⁵ is an alkyl group having 1 to 20 carbon atoms, such as methyl, ethyl, propyl, butyl, pentyl, hexyl, heptyl, octyl, nonyl, and decyl. If m is 2 or more, the alkyl groups R⁵ may be identical to or different from one another. The alkyl group R⁵ preferably has 1 to 10 carbon atoms in view of high silanol curing efficiency and easy handling. The alkyl group more preferably has one to three carbon atoms.

In Formula (SA), R⁶ may be any substituent other than an alkoxy group. Examples of the substituent include an alkyl group, a vinyl group, an epoxy group, a styryl group, a methacryloxy group, an acryloxy group, an amino group, a ureido group, a chloropropyl group, a mercapto group, a sulfide group, and an isocyanate group.

Examples of the silane alkoxide include tetramethoxysilane, tetraethoxysilane, tetrapropoxysilane, tetrabutoxysilane, tetrapentyloxysilane, tetraphenyloxysilane, trimethoxymonoethoxysilane, dimethoxydiethoxysilane, triethoxymonomethoxysilane, monomethoxytriphenyloxysilane, dimethoxydipropoxysilane, dimethoxymonoethoxymonobutoxysilane, monomethoxymonoethoxymonopropoxymonobutoxysilane, 3-glycidoxypropyltrimethoxysilane, 3-glycidoxypropyltriethoxysilane, 3-methacryloxypropyltrimethoxysilane, 3-methacyloxypropylmethyldimethoxysilane, 3-acryloxypropyltrimethoxysilane, and 3-aminopropyltrimethoxysilane.

(4) Polysilazane and Modified Polysilazane

(4.1)

The “polysilazane” is a polymer having a silicon-nitrogen bond; specifically, an inorganic polymer composed of Si—N, Si—H, and N—H and serving as a precursor for a ceramic material, such as SiO₂, Si₃N₄, or an intermediate solid solution thereof (SiOₓN_{y}). The polysilazane or the modified polysilazane is represented by Formula (I). The modified polysilazane is a compound prepared through modification of the polysilazane and containing at least one of silicon oxide, silicon nitride, and silicon oxynitride.

[F3]

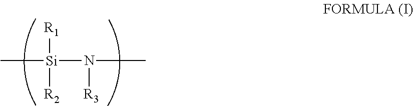

Preferably, the polysilazane is modified into silica (ceramic material) at a relatively low temperature as described in Japanese Unexamined Patent Application Publication No. H08-112879 so that the luminous material is applied to a film substrate without causing damage to the substrate.

In Formula (I), R₁, R₂, and R₃ each independently represent a hydrogen atom, an alkyl group, an alkenyl group, a cycloalkyl group, an aryl group, an alkylsilyl group, an alkylamino group, or an alkoxy group.

Perhydropolysilazane (i.e., all of R₁, R₂, and R₃ are hydrogen atoms) is particularly preferred in view of formation of a dense layer.

The use of an organopolysilazane prepared through partial substitution of the hydrogen atoms bonded to Si by an alkyl group (e.g., a methyl group) is advantageous to improve the adhesion between the luminous material and an underlying substrate, to impart toughness to a hard, brittle ceramic film composed of polysilazane, and to reduce cracking in a film having a large (average) thickness. The perhydropolysilazane and the organopolysilazane may be used alone or in combination depending on the intended application of the luminous material.

The perhydropolysilazane is presumed to have a linear-chain structure and a cyclic structure including six- and eight-membered rings. The perhydropolysilazane has a number average molecular weight (Mn) of about 600 to 2,000 (in terms of polystyrene). The perhydropolysilazane is in the form of liquid or solid depending on its molecular weight. The perhydropolysilazane is commercially available in the form of an organic solution. Such a commercial product may be used as a polysilazane-containing solution without any treatment.

Examples of other polysilazanes that convert to ceramic materials at low temperatures include a silicon alkoxide-added polysilazane prepared by reaction of silicon alkoxide with a polysilazane represented by Formula (I) (Japanese Unexamined Patent Application Publication No. H05-238827); a glycidol-added polysilazane prepared by reaction of glycidol with polysilazane (Japanese Unexamined Patent Application Publication No. H06-122852); an alcohol-added polysilazane prepared by reaction of alcohol with polysilazane (Japanese Unexamined Patent Application Publication No. H06-240208); a metal carboxylate-added polysilazane prepared by reaction of metal carboxylate with polysilazane (Japanese Unexamined Patent Application Publication No. H06-299118); an acetylacetonate complex-added polysilazane prepared by reaction of a metal-containing acetylacetonate complex with polysilazane (Japanese Unexamined Patent Application Publication No. H06-306329); and a metal particle-added polysilazane prepared by addition of fine metal particles to polysilazane (Japanese Unexamined Patent Application Publication No. H07-196986).

The material for the semiconductor nanoparticulate layer may contain an amine or a metal catalyst for promoting conversion of the polysilazane into a silicon oxide compound. Specific examples of the material include Aquamica NAX120-20, NN110, NN310, NN320, NL110A, NL120A, NL150A, NP110, NP140, and SP140 (manufactured by AZ Electronic Materials).

(4.2) Modification Process

The modification process is preferably performed on the semiconductor nanoparticles and the polysilazane. The modification process can partially or entirely convert the polysilazane into a modified polysilazane.

If both the polysilazane and the semiconductor nanoparticles are dispersed in the coating liquid for formation of a semiconductor nanoparticulate layer, the modification process is performed on a coating layer formed through application of the coating liquid onto the aforementioned film.

If the semiconductor nanoparticles are preliminarily coated with the polysilazane, the modification process may be performed on the polysilazane-coated semiconductor nanoparticles or on a coating layer containing the polysilazane-coated semiconductor nanoparticles. Alternatively, the modification process may be performed on both the polysilazane-coated semiconductor nanoparticles and the coating layer.

Specifically, the modification process involves a known treatment for conversion reaction of the polysilazane. A thermal treatment at 450° C. or higher is required for formation of a silicon oxide film or a silicon oxynitride film through substitution reaction of a silazane compound. The thermal treatment is difficult to apply to a flexible substrate, such as a plastic substrate. Thus, formation of such a film on the plastic substrate preferably involves a treatment capable of facilitating the conversion reaction at low temperature, such as plasma treatment, ozone treatment, or irradiation with UV rays.

If the modification process is performed on the coating layer containing the polysilazane, moisture is preferably removed from the layer before the modification process.

In the present invention, the modification process preferably involves irradiation with UV rays, vacuum UV rays, or plasma. Irradiation with vacuum UV rays is particularly preferred in view of effective modification of the polysilazane.

(4.2.1) Irradiation with UV Rays

The modification process preferably involves irradiation with UV rays. Ozone or active oxygen atoms produced by UV rays (i.e., UV light) have high oxidative capacity and enable formation of a silicon oxide film or a silicon oxynitride film having high density and insulating properties at low temperature.

Irradiation with UV rays is detailed in, for example, paragraphs [0049] and [0050] of Japanese Unexamined Patent Application Publication No. 2013-071390 and paragraph of Japanese Unexamined Patent Application Publication No. 2013-123895.

(4.2.2) Irradiation with Vacuum UV Rays or Excimer Laser Beam

In the present invention, irradiation with vacuum UV rays is preferred. Irradiation with vacuum UV rays involves the use of the energy of light having a wavelength of 100 to 200 nm, preferably the energy of light having a wavelength of 100 to 180 nm, the energy being greater than the interatomic bonding force in a silazane compound. Specifically, a silicon oxide film is formed at a relatively low temperature through direct cleavage of atomic bonds with only photons (i.e., a photon process) for promoting oxidation with active oxygen or ozone.

Irradiation with excimer laser beam is detailed in paragraphs [0058] to [0065] of Japanese Unexamined Patent Application Publication No. 2013-123895 and paragraphs [0150] to [0167] of Japanese Unexamined Patent Application Publication No. 2014-083691.

<<Production of Luminous Material>>

In the present invention, both the metal alkoxide and the silicon compound may be dispersed together with the semiconductor nanoparticles in the coating liquid for formation of a semiconductor nanoparticulate layer. Alternatively, the semiconductor nanoparticles may be preliminarily coated with the metal alkoxide and the silicon compound, and the coated nanoparticles may be dispersed in the coating liquid for formation of a semiconductor nanoparticulate layer. As used herein, the expression “coating of the semiconductor nanoparticles” refers to the case where the surfaces of the semiconductor nanoparticles are partially or entirely coated with the coating material.

If the metal alkoxide and the silicon compound are contained in the coating liquid for formation of a semiconductor nanoparticulate layer; i.e., if the semiconductor nanoparticles are present in proximity to the metal alkoxide and the silicon-containing compound having high oxygen barrier properties, the luminous material exhibits high durability such that the semiconductor nanoparticles are not exposed to oxygen for a long period of time. The resultant layer has high transparency.

In the present invention, particularly preferred is that the semiconductor nanoparticles are preliminarily coated with the metal alkoxide and the silicon compound, and the coated semiconductor nanoparticles are dispersed in the coating liquid for formation of a semiconductor nanoparticulate layer. The semiconductor nanoparticles may be coated with the metal alkoxide and the silicon compound by any of the following process A and process B.

Process A-1: Process of Producing Semiconductor Nanoparticles

Now will be specifically described a process of producing a luminous material containing the semiconductor nanoparticles according to the present embodiment.

Semiconductor nanoparticulate cores are synthesized in a liquid phase. For synthesis of InN semiconductor nanoparticulate cores, 1-octadecene serving as a solvent is placed in a flask, for example, and the solvent is mixed with tris (dimethylamino) indium and 1-heptadecyl-octadecylamine (HDA). The mixture is thoroughly agitated, and then the synthetic reaction is allowed to proceed at a temperature of 180 to 500° C. In this process, the core size increases with prolonged reaction time in principle. Thus, the size of InN semiconductor nanoparticulate cores can be controlled to a desired level through monitoring of the core size by photoluminescence, light absorption, or dynamic light scattering spectroscopy.

Subsequently, the mixture containing the semiconductor nanoparticulate cores is thermally reacted with raw materials for a shell layer; i.e., a reagent and an organic modifier (e.g., a surfactant or a coordinating organic solvent). The resultant reaction mixture is further thermally reacted with a metal alkoxide. In this step, the raw materials are deposited on crystals of the semiconductor nanoparticulate cores, to form a shell layer. The shell layer is chemically bonded with the metal alkoxide and the organic modifier.

Process A-2: Production of Silica-Coated Semiconductor Nanoparticles

Semiconductor nanoparticles are mixed with a silicon compound (e.g., polysilazane), and the mixture is injected into a reverse microemulsion. Thereafter, the mixture is subjected to reaction under application of, for example, an alkali, an acid, light, or heat, and the resultant solid phase is collected. Silica-coated semiconductor nanoparticles are thereby synthesized.

Process B-1: Another Process of Producing Semiconductor Nanoparticles

Now will be specifically described another process of producing semiconductor nanoparticles according to the present embodiment.

Semiconductor nanoparticulate cores are synthesized in a liquid phase. For synthesis of InN semiconductor nanoparticulate cores, 1-octadecene serving as a solvent is placed in a flask, for example, and the solvent is mixed with tris (dimethylamino) indium and 1-heptadecyl-octadecylamine (HDA). The mixture is thoroughly agitated, and then the synthetic reaction is allowed to proceed at a temperature of 180 to 500° C. In this process, the core size increases with the reaction time in principle. Thus, the size of InN semiconductor nanoparticulate cores can be controlled to a desired level through monitoring of the core size by photoluminescence, light absorption, or dynamic light scattering spectroscopy.

Subsequently, the mixture containing the semiconductor nanoparticulate cores is thermally reacted with raw materials for a shell layer; i.e., a reagent and an organic modifier (e.g., a surfactant or a coordinating organic solvent). In this step, the raw materials are deposited on crystals of the semiconductor nanoparticulate cores, to form a shell layer. The shell layer is chemically bonded with the organic modifier.

Process B-2: Production of silica-coated semiconductor nanoparticles with reaction product of metal alkoxide and silicon compound

A silicon compound (e.g., polysilazane) is reacted with a metal alkoxide in the absence or presence of an organic solvent. Semiconductor nanoparticles are injected in and mixed with the reaction mixture. The mixture is then injected into a reverse microemulsion. Thereafter, the mixture is subjected to reaction under application of, for example, an alkali, an acid, light, or heat, and the resultant solid phase is collected. Silica-coated semiconductor nanoparticles are thereby synthesized.

The molar ratio of the silicon compound to the semiconductor nanoparticles is about 1,000:1 to 100,000:1, preferably about 5,000:1 to 20,000:1. As used herein, the molar number of semiconductor nanoparticles is determined by dividing the number of the semiconductor nanoparticles (not the number of semiconductor molecules) by the Avogadro constant. The molar absorption coefficient of semiconductor nanoparticles, which is determined by the material and size of the nanoparticles, is reported in many documents. For example, CdSe, CdTe, or CdS nanoparticles are detailed in (Yu, et al., Chemistry of Materials Vol. 15, page 2854 (2003)). Supplemental data on CdTe nanoparticles having a specific size are described in (Murase, et al., Nanoscale Research Letters, Vol. 2, page 230 (2007)). The molar concentration of semiconductor nanoparticles can be readily calculated from the absorbance of a target solution by the method described in such a document. Furthermore, the molar number of the semiconductor nanoparticles contained in the solution can be calculated on the basis of the volume of an aqueous solution X added.

The mass ratio of the silicon compound to the dopant compound is preferably 1:0.05 to 1:3.9, more preferably 1:0.12 to 1:3.0, still more preferably 1:0.3 to 1:2.0.

Agitation during the reaction may be performed at any temperature. The agitation temperature is typically 5 to 50° C., preferably 10 to 40° C. The agitation time is not especially limited, but is typically one to six hours, preferably two to four hours.

Among the aforementioned processes A and B, preferred is process B including a step of preparing a mixture of the silicon compound and the metal alkoxide, and a step of reacting the mixture with the semiconductor nanoparticles, to coat the semiconductor nanoparticles with silica, because the semiconductor nanoparticles are uniformly coated with the metal alkoxide through interaction between functional groups of the organic modifier on the semiconductor nanoparticles and alkoxy groups of metal alkoxide molecules.

<<Configuration of Optical Film of the Present Invention>>

The optical film of the present invention includes a substrate and a semiconductor nanoparticulate layer disposed on the substrate, the semiconductor nanoparticulate layer being formed through application of a coating liquid containing the luminous material of the present invention (i.e., a coating liquid for formation of the semiconductor nanoparticulate layer). Next will be described layers of the optical film of the present invention and materials for the layers.

(1) Substrate

The substrate used for the optical film of the present invention may be any translucent substrate composed of glass or plastic material, for example. Examples of preferred materials for the translucent substrate include glass, quartz, and resin films. Particularly preferred is a resin film that can impart flexibility to the organic film.

The substrate may have any thickness. The substrate preferably has a thickness of 10 to 300 nm, more preferably 10 to 200 nm, still more preferably 10 to 150 nm, in view of flexibility, strength, and weight reduction.

Examples of resins constituting the resin film include polyesters, such as poly(ethylene terephthalate) (PET) and poly(ethylene naphthalate) (PEN), polyethylene, polypropylene, cellophane, cellulose esters and their derivatives, such as cellulose diacetate, cellulose triacetate (TAC), cellulose acetate butyrate, cellulose acetate propionate (CAP), cellulose acetate phthalate, and cellulose nitrate, poly(vinylidene chloride), poly(vinyl alcohol), poly(ethylene-co-vinyl alcohol), syndiotactic polystyrene, polycarbonates, norbornene resins, polymethylpentene, polyether ketones, polyimides, polyethersulfone (PES), poly(phenylene sulfide), polysulfones, polyether imide, polyether ketone imide, polyamides, fluororesins, nylon, poly(methyl methacrylate), acrylic resins, polyarylates, and cycloolefin resins, such as ARTON (trade name, manufactured by JSR Corp.) and APEL (trade name, manufactured by Mitsui Chemicals Inc.).

The resin film may be coated with a gas barrier film composed of an inorganic or organic substance, or both. The gas barrier film is preferably, for example, a gas barrier film having a water vapor transmission rate (25±0.5° C., relative humidity (90±2)% RH) of 0.01 g/(m²·24 h) or less as determined in accordance with JIS K 7129-1992. The gas barrier film is more preferably a high gas barrier film having an oxygen transmission rate of 1×10⁻³ mL/m²·24 h·atm or less as determined in accordance with JIS K7126-1987 and a water vapor transmission rate of 1×10⁻⁵ g/m²·24 h or less.

The gas barrier film may be composed of any material capable of preventing intrusion of a substance which causes degradation of the semiconductor nanoparticles, such as moisture or oxygen. Examples of the material include silicon oxide, silicon dioxide, and silicon nitride. In view of enhancement of the strength, the gas barrier film preferably has a layered structure composed of an inorganic layer and an organic material layer. The inorganic layer and the organic layer may be disposed in any order. Preferably, a plurality of inorganic layers and organic layers are alternately disposed.

The gas barrier film may be formed by any known process. Examples of the process include vacuum deposition, sputtering, reactive sputtering, molecular beam epitaxy, the ionized-cluster beam method, ion plating, plasma polymerization, atmospheric pressure plasma polymerization, plasma CVD, laser CVD, thermal CVD, and coating. In particular, the gas barrier film is preferably formed through atmospheric pressure plasma polymerization as described in Japanese Unexamined Patent Application Publication No. 2004-68143.

(2) Functional Surface Modifier

In the present invention, the semiconductor nanoparticles contained in the coating liquid for formation of a semiconductor nanoparticulate layer preferably have a surface modifier deposited near the surfaces of the nanoparticles. The surface modifier provides the semiconductor nanoparticles with high dispersion stability in the coating liquid. Deposition of the surface modifier on the surfaces of the semiconductor nanoparticles in the production thereof provides the semiconductor nanoparticles with superior properties; for example, high sphericity and narrow particle size distribution.

The functional surface modifier applicable to the present invention may be directly bonded to the surfaces of the semiconductor nanoparticles, or may be bonded through a shell (i.e., the surface modifier is directly bonded to the shell, but is not in contact with the cores of the semiconductor nanoparticles).

Examples of the surface modifier include polyoxyethylene alkyl ethers, such as polyoxyethylene lauryl ethers, polyoxyethylene stearyl ethers, and polyoxyethylene oleyl ethers; trialkylphosphines, such as tripropylphosphine, tributylphosphine, trihexylphosphine, and trioctylphosphine; polyoxyethylene alkylphenyl ethers, such as polyoxyethylene n-octylphenyl ethers and polyoxyethylene n-nonylphenyl ethers; tertiary amines, such as tri(n-hexyl)amine, tri(n-octyl)amine, and tri(n-decyl)amine; organic phosphorus compounds, such as tripropylphosphine oxide, tributylphosphine oxide, trihexylphosphine oxide, trioctylphosphine oxide, and tridecylphosphine oxide; polyethylene glycol diesters, such as polyethylene glycol dilaurate and polyethylene glycol distearate; organic nitrogen compounds, such as nitrogen-containing aromatic compounds (e.g., pyridine, lutidine, corydine, and quinolines); aminoalkanes, such as hexylamine, octylamine, decylamine, dodecylamine, tetradecylamine, hexadecylamine, and octadecylamine; dialkyl sulfides, such as dibutyl sulfide; dialkyl sulfoxides, such as dimethyl sulfoxide and dibutyl sulfoxide; organic sulfur compounds, such as sulfur-containing aromatic compounds (e.g., thiophene); higher fatty acids, such as palmitic acid, stearic acid, and oleic acid; alcohols; sorbitan fatty acid esters; fatty acid-modified polyesters; tertiary amine-modified polyurethanes; and polyethyleneimines. If the semiconductor nanoparticles are prepared by a process described below, the surface modifier is preferably a substance which is coordinated to the semiconductor nanoparticles and is stabilized in a high-temperature liquid phase. Specific examples of preferred surface modifiers include trialkylphosphines, organic phosphorus compounds, aminoalkanes, tertiary amines, organic nitrogen compounds, dialkyl sulfides, dialkyl sulfoxides, organic sulfur compounds, higher fatty acids, and alcohols. The use of such a surface modifier provides the semiconductor nanoparticles with high dispersibility in the coating liquid. The surface modifier provides the semiconductor nanoparticles with high sphericity during production thereof, and also provide the nanoparticles with sharp particle distribution.

In the present invention, the surface modifier may be a polysilazane.

(3) Semiconductor Nanoparticulate Layer

The semiconductor nanoparticulate layer contains the luminous material of the present invention. The semiconductor nanoparticulate layer may include two or more sublayers. In this case, the two or more semiconductor nanoparticulate sublayers preferably contain different types of semiconductor nanoparticles having different emission wavelengths.

The semiconductor nanoparticulate layer is formed through application of the coating liquid onto the substrate, followed by drying.

The coating liquid may be applied onto the substrate by any appropriate process. Specific examples of the process include spin coating, roll coating, flow coating, ink jetting, spray coating, printing, dip coating, casting, bar coating, and gravure printing.

The solvent used for preparing the coating liquid for formation of the semiconductor nanoparticulate layer may be any solvent which does not react with the semiconductor nanoparticles, the polysilazane, or the modified polysilazane. The solvent may be toluene, for example.

After application of the coating liquid for formation of the semiconductor nanoparticulate layer, the resultant coating layer is dried, and then the polysilazane is preferably modified partially or entirely by the aforementioned process, to form a modified polysilazane.

The semiconductor nanoparticulate layer preferably contains an additional resin material, particularly preferably a UV-curable resin. If the semiconductor nanoparticulate layer contains a UV-curable resin; i.e., the coating liquid contains a UV-curable resin, the coating layer formed through application of the coating liquid is irradiated with UV rays. Irradiation with UV rays may also serve as the aforementioned polysilazane modifying process.

The semiconductor nanoparticulate layer may have any thickness, and the thickness may be appropriately determined depending on the intended application of the optical film.

(4) Resin Material

The semiconductor nanoparticulate layer of the optical film of the present invention preferably contains a resin material, more preferably a UV-curable resin.

Examples of preferred UV-curable resins include UV-curable urethane acrylate resins, UV-curable polyester acrylate resins, UV-curable epoxy acrylate resins, UV-curable polyol acrylate resins, and UV-curable epoxy resins. Particularly preferred are UV-curable acrylate resins.

In general, the UV-curable urethane acrylate resin is readily prepared by reacting a polyester polyol with an isocyanate monomer or prepolymer, and reacting the resultant product with an acrylate monomer having a hydroxy group, such as 2-hydroxyethyl acrylate, 2-hydroxyethyl methacrylate (hereafter “acrylate” and “methacrylate” will be collectively referred to as “acrylate”), or 2-hydroxypropyl acrylate. The UV-curable urethane acrylate may be one described in Japanese Unexamined Patent Application Publication No. S59-151110. The UV-curable urethane acrylate is preferably, for example, a mixture of Unidic 17-806 (manufactured by DIC Corporation) (100 parts) and Coronate L (manufactured by Nippon Polyurethane Industry Co., Ltd.) (1 part).

In general, the UV-curable polyester acrylate resin is readily prepared by reacting a polyester polyol with a monomer of 2-hydroxyethyl acrylate or 2-hydroxy acrylate. The UV-curable polyester acrylate resin may be one described in Japanese Unexamined Patent Application Publication No. S59-151112.

Specific examples of the UV-curable epoxy acrylate resin include those prepared by reacting an epoxy acrylate oligomer with a reactive diluent and a photopolymerization initiator. The UV-curable epoxy acrylate resin may be one described in Japanese Unexamined Patent Application Publication No. H01-105738.

Specific examples of the UV-curable polyol acrylate resin include trimethylolpropane triacrylate, ditrimethylolpropane tetraacrylate, pentaerythritol triacrylate, pentaerythritol tetraacrylate, dipentaerythritol hexaacrylate, and alkyl-modified dipentaerythritol pentaacrylate.

The semiconductor nanoparticulate layer containing a resin material described above is formed through application of the coating liquid by a known process, such as gravure coating, dip coating, reverse coating, wire bar coating, die coating, or ink jetting, followed by thermal drying and UV curing. The coating layer has a wet thickness of appropriately 0.1 to 40 μm, preferably 0.5 to 30 μm, and has a mean dry thickness of 0.1 to 30 μm, preferably 1 to 20 μm.

The semiconductor nanoparticulate layer may contain any resin material other than UV-curable resins. Examples of other possible resin materials include thermoplastic resins, such as poly(methylmethacrylate) (PMMA) resins; and thermosetting resins, such as thermosetting urethane resins prepared from acrylic polyols and isocyanate prepolymers, phenolic resins, urea-melamine resins, epoxy resins, unsaturated polyester resins, and silicone resins.

<<Configuration of Light-Emitting Device of the Present Invention>>

The optical film of the present invention having the aforementioned configuration is applicable to various light-emitting devices. For example, the optical film can be used as a high-intensity film disposed between a light source and a polarizer in an LCD.

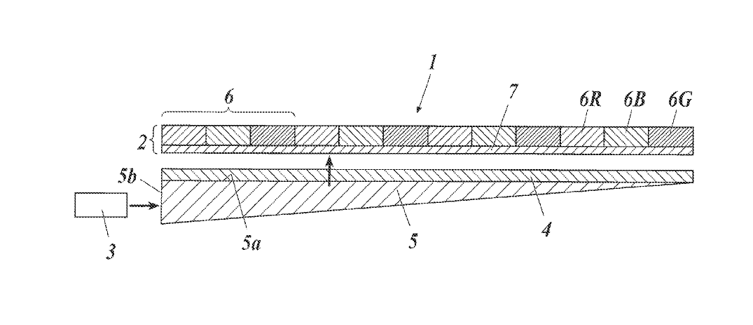

FIG. 1 is a schematic cross-sectional view of a display (light-emitting device) according to an embodiment of the present invention, the display including the optical film of the present invention.

The display 1 includes a primary light source 3 and an image display panel 2 disposed in a light path from the primary light source 3. The image display panel 2 includes an image display layer 7, such as a liquid crystal layer. For the sake of clarity, FIG. 1 does not illustrate, for example, a substrate for supporting the image display layer 7, electrodes and a drive circuit for driving the image display layer 7, and a film for orienting liquid crystal molecules in the image display layer 7. In this embodiment, the image display layer 7 is pixelated, and individual pixels of the image display layer 7 can be independently driven.

The display 1 is designed to provide a color image. Thus, the image display panel 2 includes color filter units 6. For a full-color red/green/blue (RGB) display shown in FIG. 1, each color filter unit 6 in the image display panel 2 consists of a red color filter 6R, a blue color filter 6B, and a green color filter 6G. Individual color filters are aligned with pixels or subpixels of the image display layer 7.

The image display panel 2 may be of any traditional type, regardless of the characteristics of the color filter units 6 (further detailed below). The present invention is generally applicable to any appropriate image display layer.

In the display 1, the aforementioned light source includes the primary light source 3 that is driven to emit light, and an optical film 4 disposed in a light path from the primary light source 3 and containing the semiconductor nanoparticles of the present invention. When the primary light source 3 is driven to emit light, the light from the primary light source 3 is absorbed by the optical film 4 and then is re-emitted at a different wavelength.

The primary light source 3 may include one or more light-emitting diodes (LEDs).

The display 1 further includes an optical system such that the image display panel 2 is substantially uniformly irradiated with light from the light source. In the embodiment shown in FIG. 1, the optical system includes a light guide 5 having a light emission surface having substantially the same area as the surface of the image display panel 2. Light from the primary light source 3 is incident on the light guide 5 through a side face 5b, and is reflected in the light guide 5 in accordance with the principle of total internal reflection. Finally, the reflected light is emitted through the light emission surface 5a of the light guide 5. The optical film 4 of the present invention is disposed on the light emission surface 5a.

Although the display 1 shown in FIG. 1 includes the transmissive image display panel 2, the present invention may be applied to a semi-transmssive display.

The optical film 4 is preferably composed of two or more different materials such that, when the optical film 4 is irradiated with light from the primary light source 3, the optical film 4 emits light having different wavelengths which are different from the wavelength of the light emitted from the primary light source 3. For example, if the optical film 4 is composed of three different materials that re-emit light in the red, green, and blue regions of the spectrum, the optical film 4 can emit white light. The primary light source 3 may emit light outside the visible spectrum (e.g., light in the UV region).

According to the present invention, the optical film 4 contains at least one type of semiconductor nanoparticles. The semiconductor nanoparticles exhibit a narrow emission spectrum having a full width at half maximum (FWHM) of preferably 80 nm or less, more preferably 60 nm or less.

The color filter unit 6 further includes a color filter with narrow band transmission. The filter with narrow band transmission exhibits a transmittance spectrum having a full width at half maximum (FWHM) of preferably 100 nm or less, particularly preferably 80 nm or less.

As illustrated in FIG. 1, the optical film 4 including a semiconductor nanoparticulate layer is attached to the light guide 5. Alternatively, the semiconductor nanoparticles may be incorporated in an appropriate transparent matrix; for example, in a transparent resin for a light guide that is molded into a desired shape and then bent.

### EXAMPLES

The present invention will now be described in detail by way of Examples, which should not be construed as limiting the invention thereto. Unless otherwise specified, the terms “part(s)” and “%” in the following description indicate “part(s) by mass” and “mass %,” respectively.

### Example 1

### Synthesis of Semiconductor Nanoparticles

### Synthesis Example 1-1

### Semiconductor Nanoparticles A1 (InP/ZnS)

Indium myristate (0.1 mmol), stearic acid (0.1 mmol), trimethylsilylphosphine (0.1 mmol), dodecanethiol (0.1 mmol), zinc undecylenate (0.1 mmol), and octadecene (8 mL) were placed in a three-neck flask, and the mixture was refluxed at 300° C. for one hour under a nitrogen atmosphere, to yield InP/ZnS (semiconductor nanoparticles A1). As used herein, semiconductor nanoparticles composed of an InP core and a ZnS shell are represented as “InP/ZnS.”

The semiconductor nanoparticles A1 were directly observed with a transmission electron microscope, and were determined to have an InP/ZnS core-shell structure such that the InP core was coated with the ZnS shell. This microscopic observation showed that the InP/ZnS semiconductor nanoparticles synthesized by the aforementioned process had a core particle size of 2.1 to 3.8 nm and a core particle size distribution of 6 to 40%. This observation was performed with a transmission electron microscope JEM-2100 manufactured by JEOL Ltd.

The optical characteristics of the InP/ZnS semiconductor nanoparticles were determined through analysis of the octadecene mixture containing the semiconductor nanoparticles. This analysis showed that the semiconductor nanoparticles had a peak emission wavelength of 430 to 720 nm, an emission half width of 35 to 90 nm, and a maximum emission efficiency of 70.9%. The emission characteristics of the InP/ZnS semiconductor nanoparticles were determined with a fluorescence spectrophotometer FluoroMax-4 manufactured by JOBIN YVON, and the absorption spectrum of the InP/ZnS semiconductor nanoparticles was measured with a spectrophotometer U-4100 manufactured by Hitachi High-Technologies Corporation.

### Synthesis Example 1-2

### Silica-Coated Semiconductor Nanoparticles A2

The semiconductor nanoparticles A1 (0.4 mL, inorganic components: about 70 mg) were dried under vacuum.

Subsequently, triethyl orthosilicate (TEOS) (0.6 mL) was added to the semiconductor nanoparticles A1 to prepare a clear mixture, and the mixture was stored for incubation under N₂ overnight. The mixture was then added to 10 mL of a reverse microemulsion (cyclohexane/CO-520 (surfactant described below), 18 mL/1.35 g) in a 50-mL flask under agitation at 600 rpm. The mixture was agitated for 15 minutes, and then 4% NH₄OH (0.1 mL) was added to the mixture for initiation of reaction. On the following day, the reaction was terminated through centrifugation, and the resultant solid phase was collected. The resultant particles were washed twice with cyclohexane (20 mL) and then dried under vacuum, to yield silica-coated semiconductor nanoparticles A2.

CO-520: Igepal (Registered Trademark) CO-520 (Nonionic Surfactant: Polyoxyethylene (5) Nonylphenyl Ether)

The semiconductor nanoparticles A2 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 90 nm, and a maximum emission efficiency of 70.9%.

### Synthesis Example 1-3

### Silica-Coated Semiconductor Nanoparticles A3

The semiconductor nanoparticles A1 (0.4 mL, inorganic components: about 70 mg) were dried under vacuum. Subsequently, triethyl orthosilicate (TEOS) (0.6 mL) was mixed with aluminum triisopropoxide (0.3 mmol) under agitation at 80° C. for one hour. The mixture was added to the semiconductor nanoparticles A1 to prepare a clear mixture, and the mixture was stored for incubation under N₂ overnight. The mixture was then added to 10 mL of a reverse microemulsion (cyclohexane/CO-520, 18 mL/1.35 g) in a 50-mL flask under agitation at 600 rpm. The mixture was agitated for 15 minutes, and then 4% NH₄OH (0.1 mL) was added to the mixture for initiation of reaction. On the following day, the reaction was terminated through centrifugation, and the resultant solid phase was collected. The resultant particles were washed twice with cyclohexane (20 mL) and then dried under vacuum, to yield silica-coated semiconductor nanoparticles A3.

The semiconductor nanoparticles A3 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 75 nm, and a maximum emission efficiency of 74.1%.

### Synthesis Example 1-4

### Semiconductor Nanoparticles A4

Semiconductor nanoparticles A4 were synthesized as in Synthesis Example 1-3, except that aluminum triisopropoxide was replaced with copper isopropoxide.

The semiconductor nanoparticles A4 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 72.8%.

### Synthesis Example 1-5

### Silica-Coated Nanoparticles A5

The semiconductor nanoparticles A1 (0.4 mL, inorganic components: about 70 mg) were dried under vacuum. Subsequently, perhydropolysilazane (Aquamica NN120-10, non-catalyst type, manufactured by AZ Electronic Materials) (0.6 mL) was mixed with iron isopropoxide (0.15 mmol) under agitation at 80° C. for one hour. The mixture was added to the semiconductor nanoparticles A1 to prepare a clear mixture, and the mixture was stored for incubation under N₂ overnight. The mixture was then added to 10 mL of a reverse microemulsion (cyclohexane/CO-520, 18 mL/1.35 g) in a 50-mL flask under agitation at 600 rpm. The mixture was agitated for 15 minutes, and then 4% NH₄OH (0.1 mL) was added to the mixture for initiation of reaction. On the following day, the reaction was terminated through centrifugation, and the resultant solid phase was collected. The resultant particles were washed twice with cyclohexane (20 mL) and then dried under vacuum, to yield perhydropolysilazane-coated semiconductor nanoparticles A5.

The semiconductor nanoparticles A5 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 1-6

### Silica-Coated Semiconductor Nanoparticles A6

Semiconductor nanoparticles A6 were synthesized as in Synthesis Example 1-5, except that iron isopropoxide was replaced with aluminum tri-n-butoxide.

The semiconductor nanoparticles A6 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 70 nm, and a maximum emission efficiency of 74.1%.

### Synthesis Example 1-7

### Silica-Coated Semiconductor Nanoparticles A7

The semiconductor nanoparticles A1 (0.4 mL, inorganic components: about 70 mg) were dried under vacuum. Separately, aluminum triisopropoxide and an equi-molar amount of 1-dodecanol were heated under agitation, and 2-propanol was removed, to yield dodecyloxyaluminum.

Subsequently, perhydropolysilazane (Aquamica NN120-10, non-catalyst type, manufactured by AZ Electronic Materials) (0.6 mL) was mixed with dodecyloxyaluminum (0.15 mmol) under agitation at 80° C. for one hour. Thereafter, the mixture was dispersed in toluene. While the dispersion (5 mL) was agitated at 40° C., a mixture of perhydropolysilazane (Aquamica NN120-10, non-catalyst type, manufactured by AZ Electronic Materials) (0.5 mL) and tridodecyloxyaluminum was added to the dispersion, and the mixture was agitated at about 70° C. for three hours. The resultant particles were dried under vacuum, to yield perhydropolysilazane-coated semiconductor nanoparticles A7.

The semiconductor nanoparticles A7 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 70 nm, and a maximum emission efficiency of 76.2%.

### Synthesis Example 1-8

### Silica-Coated Semiconductor Nanoparticles A8

The semiconductor nanoparticles A1 (0.4 mL, inorganic components: about 70 mg) were dried under vacuum. Subsequently, perhydropolysilazane (Aquamica NN120-10, non-catalyst type, manufactured by AZ Electronic Materials) (0.6 mL) was mixed with aluminum butoxide (0.15 mmol) under agitation at 80° C. for one hour. Thereafter, the mixture was dispersed in toluene. While the dispersion (5 mL) was agitated at 40° C., a mixture of perhydropolysilazane (Aquamica NN120-10, non-catalyst type, manufactured by AZ Electronic Materials) (0.5 mL) and aluminum tri-n-butoxide was added to the dispersion, and the mixture was agitated at about 40° C. for one hour. The resultant particles were dried under vacuum and irradiated with excimer laser beams from an excimer laser apparatus described below, to yield semiconductor nanoparticles A8 coated with the polysilazane partially modified into silica.

The semiconductor nanoparticles A8 were analyzed as in the semiconductor nanoparticles A1. The analysis showed that the semiconductor nanoparticles had a peak emission wavelength of 390 to 700 nm, an emission half width of 30 to 70 nm, and a maximum emission efficiency of 77.1%.

<Excimer Laser Apparatus>

Apparatus: MODEL: MECL-M-1-200 manufactured by M. D. COM, Inc.

Irradiation wavelength: 172 nm

Lamp filler gas: Xe

### <Modification Conditions>

The semiconductor nanoparticles fixed on an operation stage were modified under the following conditions:

Light intensity of excimer lamp: 130 mW/cm² (172 nm)

Distance between sample and light source: 1 mm

Stage heating temperature: 70° C.

Oxygen concentration in apparatus: 0.01%

Excimer laser irradiation period: 5 seconds

### Synthesis Example 1-9

### Silica-Coated Semiconductor Nanoparticles A9

Semiconductor nanoparticles A9 were synthesized as in Synthesis Example 1-8, except that aluminum butoxide was replaced with aluminum ethylacetoacetate diisopropylate.

The semiconductor nanoparticles A9 were analyzed as in the semiconductor nanoparticles A1. The analysis showed that the semiconductor nanoparticles had a peak emission wavelength of 390 to 700 nm, an emission half width of 35 to 70 nm, and a maximum emission efficiency of 77.4%.

### Synthesis Example 1-10

### Silica-Coated Semiconductor Nanoparticles A10

Semiconductor nanoparticles A10 were synthesized as in Synthesis Example 1-8, except that aluminum butoxide was replaced with aluminum diisopropylate mono-sec-butylate.

The semiconductor nanoparticles A10 were analyzed as in the semiconductor nanoparticles A1. The analysis showed that the semiconductor nanoparticles had a peak emission wavelength of 390 to 700 nm, an emission half width of 35 to 70 nm, and a maximum emission efficiency of 76.8%.

### Synthesis Example 1-11

### Silica-Coated Semiconductor Nanoparticles A11

Semiconductor nanoparticles A11 were synthesized as in Synthesis Example 1-8, except that aluminum butoxide was replaced with tridodecyloxyaluminum.

The semiconductor nanoparticles A11 were analyzed as in the semiconductor nanoparticles A1. The analysis showed that the semiconductor nanoparticles had a peak emission wavelength of 390 to 700 nm, an emission half width of 35 to 70 nm, and a maximum emission efficiency of 77.7%.

### Synthesis Example 2-1

### Semiconductor Nanoparticles B1

Indium myristate (0.1 mmol), stearic acid (0.1 mmol), trimethylsilylphosphine (0.1 mmol), dodecanethiol (0.1 mmol), zinc undecylenate (0.1 mmol), and octadecene (8 mL) were placed in a three-neck flask, and the mixture was refluxed at 300° C. for one hour under a nitrogen atmosphere, to yield InP/ZnS (semiconductor nanoparticles A1). Subsequently, the semiconductor nanoparticles A1 were thermally reacted with iron isopropoxide (Fe(OiPr)₃) (0.1 mmol), to yield semiconductor nanoparticles B1 (InP/ZnS).

The semiconductor nanoparticles B1 were analyzed as in the semiconductor nanoparticles A1. The analysis showed that the semiconductor nanoparticles had a peak emission wavelength of 400 to 700 nm, an emission half width of 35 to 85 nm, and a maximum emission efficiency of 71.9%.

### Synthesis Example 2-2

### Silica-Coated Semiconductor Nanoparticles B2

The semiconductor nanoparticles B1 (0.4 mL, inorganic components: about 70 mg) were dried under vacuum. Subsequently, triethyl orthosilicate (TEOS) (0.6 mL) was added to the semiconductor nanoparticles B1 to prepare a clear mixture, and the mixture was stored for incubation under N₂ overnight. The mixture was then added to 10 mL of a reverse microemulsion (cyclohexane/CO-520, 18 mL/1.35 g) in a 50-mL flask under agitation at 600 rpm. The mixture was agitated for 15 minutes, and then 4% NH₄OH (0.1 mL) was added to the mixture for initiation of reaction. On the following day, the reaction was terminated through centrifugation, and the resultant solid phase was collected. The resultant particles were washed twice with cyclohexane (20 mL) and then dried under vacuum, to yield silica-coated semiconductor nanoparticles B2.

The semiconductor nanoparticles B2 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 90 nm, and a maximum emission efficiency of 72.5%.

### Synthesis Example 3-1

### Semiconductor Nanoparticles C1

Se powder (0.01 mmol) was added to trioctylphosphine (TOP) (0.02 mmol), and the mixture was heated to 150° C. (under a stream of nitrogen), to prepare a TOP-Se stock solution. Separately, cadmium oxide (CdO) (0.004 mmol) and stearic acid (0.03 mmol) were placed in a three-neck flask and heated to 150° C. in an argon atmosphere for dissolution of CdO. The resultant CdO solution was cooled to room temperature. The CdO solution was mixed with trioctylphosphine oxide (TOPO) (0.02 mmol) and 1-heptadecyloctadecylamine (HDA) (0.05 mmol), the mixture was re-heated to 150° C., and the TOP-Se stock solution was quickly added to the mixture. Thereafter, the temperature of the chamber was increased to 220° C. and further increased to 250° C. at a constant rate (0.25° C./minute) over 120 minutes. The temperature was then lowered to 100° C., and zinc acetate dihydrate was added to and dissolved in the mixture under agitation. Thereafter, a solution of hexamethyldisilylthiane in trioctylphosphine was added dropwise to the mixture, and the mixture was agitated for several hours until termination of the reaction, to yield CdSe/ZnS (semiconductor nanoparticles C1).

The semiconductor nanoparticles C1 were directly observed with a transmission electron microscope as in the nanoparticles A1, and were determined to have a CdSe/ZnS core-shell structure such that the CdSe core was coated with the ZnS shell. This microscopic observation showed that the CdSe/ZnS semiconductor nanoparticles had a core particle size of 2.0 to 4.0 nm and a core particle size distribution of 6 to 40%. The analysis of optical characteristics showed that the semiconductor nanoparticles had a peak emission wavelength of 410 to 700 nm, an emission half width of 35 to 90 nm, and a maximum emission efficiency of 73.9%.

### Synthesis Example 3-2

### Silica-Coated Semiconductor Nanoparticles C2

The semiconductor nanoparticles C1 (0.4 mL, inorganic components: about 70 mg) were dried under vacuum. Subsequently, triethyl orthosilicate (TEOS) (0.6 mL) was added to the semiconductor nanoparticles C to prepare a clear mixture, and the mixture was stored for incubation under N₂ overnight. The mixture was then added to 10 mL of a reverse microemulsion (cyclohexane/CO-520, 18 mL/1.35 g) in a 50-mL flask under agitation at 600 rpm. The mixture was agitated for 15 minutes, and then 4% NH₄OH (0.1 mL) was added to the mixture for initiation of reaction. On the following day, the reaction was terminated through centrifugation, and the resultant solid phase was collected. The resultant particles were washed twice with cyclohexane (20 mL) and then dried under vacuum, to yield silica-coated semiconductor nanoparticles C2.

The semiconductor nanoparticles C2 were analyzed as in the semiconductor nanoparticles A1. The analysis showed that the silica-coated semiconductor nanoparticles had a particle size of 70 to 100 nm, a peak emission wavelength of 400 to 700 nm, an emission half width of 35 to 90 nm, and a maximum emission efficiency of 74.2%.

### Synthesis Example 3-3

### Silica-Coated Semiconductor Nanoparticles C3

Semiconductor nanoparticles C3 were synthesized as in Synthesis Example 1-3, except that the semiconductor nanoparticles A1 were replaced with the semiconductor nanoparticles C1, and aluminum triisopropoxide was replaced with iron isopropoxide.

The semiconductor nanoparticles C3 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 74.8%.

### Synthesis Example 3-4

### Silica-Coated Semiconductor Nanoparticles C4

Semiconductor nanoparticles C4 were synthesized as in Synthesis Example 1-5, except that the semiconductor nanoparticles A1 were replaced with the semiconductor nanoparticles C1.

The semiconductor nanoparticles C4 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 75 nm, and a maximum emission efficiency of 74.8%.

### Synthesis Example 4-1

### Semiconductor Nanoparticles D1

Se powder (0.01 mmol) was added to trioctylphosphine (TOP) (0.02 mmol), and the mixture was heated to 150° C. (under a stream of nitrogen), to prepare a TOP-Se stock solution. Separately, cadmium oxide (CdO) (0.004 mmol) and stearic acid (0.03 mmol) were placed in a three-neck flask and heated to 150° C. in an argon atmosphere for dissolution of CdO. The resultant CdO solution was cooled to room temperature. The CdO solution was mixed with trioctylphosphine oxide (TOPO) (0.02 mmol) and 1-heptadecyloctadecylamine (HDA) (0.05 mmol), the mixture was re-heated to 150° C., and the TOP-Se stock solution was quickly added to the mixture. Thereafter, the temperature of the chamber was increased to 220° C. and further increased to 250° C. at a constant rate (0.25° C./minute) over 120 minutes. The temperature was then lowered to 100° C., and zinc acetate dihydrate was added to and dissolved in the mixture under agitation. Thereafter, a solution of hexamethyldisilylthiane in trioctylphosphine was added dropwise to the mixture, and the mixture was agitated for several hours until termination of the reaction, to yield CdSe/ZnS (semiconductor nanoparticles C1). The semiconductor nanoparticles C1 were thermally reacted with iron isopropoxide (Fe(OiPr)₃) (0.2 mmol), to yield semiconductor nanoparticles D1′ (CdSe/ZnS).

The semiconductor nanoparticles D1′ (0.4 mL, inorganic components: about 70 mg) were dried under vacuum. Subsequently, triethyl orthosilicate (TEOS) (0.6 mL) was added to the semiconductor nanoparticles D1′ to prepare a clear mixture, and the mixture was stored for incubation under N₂ overnight. The mixture was then added to 10 mL of a reverse microemulsion (cyclohexane/CO-520, 18 mL/1.35 g) in a 50-mL flask under agitation at 600 rpm. The mixture was agitated for 15 minutes, and then 4% NH₄OH (0.1 mL) was added to the mixture for initiation of reaction. On the following day, the reaction was terminated through centrifugation, and the resultant solid phase was collected. The resultant particles were washed twice with cyclohexane (20 mL) and then dried under vacuum, to yield silica-coated semiconductor nanoparticles D1.

The semiconductor nanoparticles D1 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.7%.

### Synthesis Example 4-2

### Semiconductor Nanoparticles D2

Semiconductor nanoparticles D2 were synthesized as in Synthesis Example 4-1, except that iron isopropoxide was replaced with triisopropyl borate.

The semiconductor nanoparticles D2 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 4-3

### Semiconductor Nanoparticles D3

Semiconductor nanoparticles D3 were synthesized as in Synthesis Example 4-1, except that iron isopropoxide was replaced with magnesium n-propoxide.

The semiconductor nanoparticles D3 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.7%.

### Synthesis Example 4-4

### Semiconductor Nanoparticles D4

Semiconductor nanoparticles D4 were synthesized as in Synthesis Example 4-1, except that iron isopropoxide was replaced with titanium tetrastearylalkoxide.

The semiconductor nanoparticles D4 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 4-5

### Semiconductor Nanoparticles D5

Semiconductor nanoparticles D5 were synthesized as in Synthesis Example 4-1, except that iron isopropoxide was replaced with calcium isopropoxide.

The semiconductor nanoparticles D5 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 4-6

### Semiconductor Nanoparticles D6

Semiconductor nanoparticles D6 were synthesized as in Synthesis Example 4-1, except that iron isopropoxide was replaced with zinc tert-butoxide.

The semiconductor nanoparticles D6 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 4-7

### Semiconductor Nanoparticles D7

Semiconductor nanoparticles D7 were synthesized as in Synthesis Example 4-1, except that iron isopropoxide was replaced with gallium isopropoxide.

The semiconductor nanoparticles D7 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 4-8

### Semiconductor Nanoparticles D8

Semiconductor nanoparticles D8 were synthesized as in Synthesis Example 4-1, except that iron isopropoxide was replaced with zirconium isopropoxide.

The semiconductor nanoparticles D8 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

### Synthesis Example 4-9

### Semiconductor Nanoparticles D9

Semiconductor nanoparticles D9 were synthesized as in Synthesis Example 4-1, except that iron isopropoxide was replaced with indium isopropoxide.

The semiconductor nanoparticles D9 were analyzed as in the semiconductor nanoparticles A1. The analysis showed that the silica-coated semiconductor nanoparticles had a particle size of 70 to 100 nm, a peak emission wavelength of 390 to 700 nm, an emission half width of 35 to 80 nm, and a maximum emission efficiency of 73.5%.

The semiconductor nanoparticles A3 to A11, B2, C3, C4, and D1 to D9 were subjected to energy dispersive X-ray spectrometry (EDS) analysis for determining the compositions of the layers of each nanoparticle observed in a TEM image. The spectrum of the outermost layer of each nanoparticle exhibited the peaks of oxygen and elements derived from the silicon compound used. The spectrum of the shell exhibited the peaks of the metal of the metal alkoxide used, carbon, and elements derived from the semiconductor nanoparticles. Analysis and quantification of the peak intensities suggested that each type of the semiconductor nanoparticles contain the metal alkoxide.

Optical films 1 to 34 were formed from the above-prepared semiconductor nanoparticles A1 to A10, B1, B2, C1 to C4, and D1˜D9 by processes described below.

<<Formation of Optical Film 1>>

Red and green light-emitting components were prepared from the semiconductor nanoparticles A1 through regulation of the particle sizes. The red light-emitting component (0.75 mg) and the green light-emitting component (4.12 mg) were dispersed in toluene, and a PMMA resin solution was added to the dispersion, to prepare a coating liquid for formation of a semiconductor nanoparticulate layer, the coating liquid containing the semiconductor nanoparticles in an amount of 1 mass %.

The coating liquid was applied to a polyester film (KDL86WA, manufactured by Teijin DuPont Films Japan Limited) having a thickness of 125 μm and having both surfaces provided with high coatability, so that the resultant coating layer had a dry thickness of 100 μm, followed by drying at 60° C. for three minutes, to form an optical film 1 for comparison.

<<Formation of Optical Films 2 to 5>>

Optical films 2 to 5 were formed as in the optical film 1, except that the semiconductor nanoparticles A1 were replaced with the semiconductor nanoparticles A2 to A4 and B1 shown in Table 1.

<<Formation of Optical Film 6>>

Red and green light-emitting components were prepared from the semiconductor nanoparticles A1 contained in the semiconductor nanoparticles A4 through regulation of the particle sizes. The red light-emitting component (0.75 mg) and the green light-emitting component (4.12 mg) were dispersed in toluene. Separately, a photopolymerization initiator Irgacure 184 (manufactured by BASF Japan Ltd.) was dissolved in a UV-curable resin Unidic V-4025 (manufactured by DIC Corporation) at a solid content ratio (mass %) of 95/5 (resin/initiator), to prepare a UV-curable resin solution. The solution was added to the toluene dispersion, to prepare a coating liquid for formation of a semiconductor nanoparticulate layer, the coating liquid containing the semiconductor nanoparticles in an amount of 1 mass %.

The coating liquid was applied to a polyester film (KDL86WA, manufactured by Teijin DuPont Films Japan Limited) having a thickness of 125 μm and having both surfaces provided with high coatability, so that the resultant coating layer had a dry thickness of 100 μm, followed by drying at 60° C. for three minutes. Thereafter, the coating layer was cured with a high-pressure mercury lamp (0.5 J/cm²) in air (corresponding to “UV” in Tables 1 and 2), to form an optical film 6 of the present invention.

<<Formation of Optical Films 7 to 25>>

Optical films 7 to 25 were formed as in the optical film 6, except that the semiconductor nanoparticles A4 were replaced with nanoparticles shown in Tables 1 and 2.

<<Formation of Optical Film 26>>

A coating liquid for formation of a semiconductor nanoparticulate layer was prepared as in the coating liquid for the optical film 19, except that the semiconductor nanoparticles A6 were replaced with the semiconductor nanoparticles A8.

The resultant coating liquid was applied to a polyester film (KDL86WA, manufactured by Teijin DuPont Films Japan Limited) having a thickness of 125 μm and having both surfaces provided with high coatability, so that the resultant coating layer had a dry thickness of 100 μm, followed by drying at 60° C. for three minutes. Thereafter, the coating layer was cured with a high-pressure mercury lamp (0.5 J/cm²) in air and irradiated with excimer laser beams from an excimer laser apparatus described below (corresponding to “UV+VUV” in Table 2), to form an optical film 26 of the present invention.

<Excimer Laser Apparatus>

Apparatus: MODEL: MECL-M-1-200 manufactured by M. D. COM, Inc.

Irradiation wavelength: 172 nm

Lamp filler gas: Xe

### <Modification Conditions>

The coating-liquid-applied film fixed on an operation stage was modified under the following conditions:

Light intensity of excimer lamp: 130 mW/cm² (172 nm)

Distance between sample and light source: 1 mm

Stage heating temperature: 70° C.

Oxygen concentration in apparatus: 0.01%

Excimer laser irradiation period: 5 seconds

<<Formation of Optical Film 27>>

Red and green light-emitting components were prepared from the semiconductor nanoparticles C1 through regulation of the particle sizes. The red light-emitting component (0.75 mg) and the green light-emitting component (4.12 mg) were dispersed in toluene, and perhydrosilsesquioxane (HSQ; FOX14, manufactured by Dow Corning Toray Co., Ltd.) and copper isopropoxide were added to the dispersion, to prepare a coating liquid for formation of a semiconductor nanoparticulate layer, the coating liquid containing the semiconductor nanoparticles in an amount of 1 mass %.

The coating liquid was applied to a polyester film (KDL86WA, manufactured by Teijin DuPont Films Japan Limited) having a thickness of 125 μm and having both surfaces provided with high coatability, so that the resultant coating layer had a dry thickness of 100 μm, followed by drying at 60° C. for one hour, to form an optical film 27.

<<Formation of Optical Film 28>>

An optical film 28 was formed as in the optical film 27, except that the drying conditions were changed from 60° C. for one hour to 60° C. for five minutes, and the coating layer was irradiated with excimer laser beams from the aforementioned excimer laser apparatus.

<<Formation of Optical Film 29>>

An optical film 29 was formed as in the optical film 28, except that copper isopropoxide was not added.

<<Formation of Optical Film 30>>

An optical film 30 was formed as in the optical film 28, except that the semiconductor nanoparticles C1 were replaced with the semiconductor nanoparticles A1.

<<Formation of Optical Film 31>>

An optical film 31 was formed as in the optical film 28, except that the perhydrosilsesquioxane (HSQ) was replaced with perhydropolysilazane (Aquamica NN120-10, non-catalyst type, manufactured by AZ Electronic Materials).

<<Formation of Optical Film 32>>

An optical film 32 was formed as in the optical film 26, except that the substrate was replaced with a polycarbonate film (Pure Ace WR-S5, manufactured by Teijin Chemicals Ltd.) having a thickness of 100 μm.

<<Formation of Optical Film 33>>

An optical film 33 was formed as in the optical film 26, except that the substrate was replaced with a triacetate film (manufactured by Konica Minolta, Inc.) having a thickness of 100 μm.

<<Formation of Optical Film 34>>

Red and green light-emitting components were prepared from the semiconductor nanoparticles A10 through regulation of the particle sizes. The red light-emitting component (0.75 mg) was dispersed in toluene. Separately, a photopolymerization initiator Irgacure 184 (manufactured by BASF Japan Ltd.) was dissolved in a UV-curable resin Unidic V-4025 (manufactured by DIC Corporation) at a solid content ratio (mass %) of 95/5 (resin/initiator), to prepare a UV-curable resin solution. The solution was added to the toluene dispersion, to prepare a coating liquid for formation of a red light-emitting semiconductor nanoparticulate layer, the coating liquid containing the semiconductor nanoparticles in an amount of 1 mass %. Similarly, the green light-emitting component (4.12 mg) was dispersed in toluene, to prepare a coating liquid for formation of a green light-emitting semiconductor nanoparticulate layer.

The coating liquid for formation of a red light-emitting semiconductor nanoparticulate layer was applied to a polyester film (KDL86WA, manufactured by Teijin DuPont Films Japan Limited) having a thickness of 125 μm and having both surfaces provided with high coatability, so that the resultant coating layer had a dry thickness of 50 μm, followed by drying at 60° C. for three minutes. Thereafter, the coating layer was cured with a high-pressure mercury lamp (0.5 J/cm²) in air. Subsequently, the coating liquid for formation of a green light-emitting semiconductor nanoparticulate layer was applied to the red light-emitting semiconductor nanoparticulate layer, and the resultant coating layer was cured as in the red light-emitting layer, to form an optical film 34 of the present invention having a two-layer structure including the red and green light-emitting semiconductor nanoparticulate layers.

<<Evaluation of Optical Film>>

The resultant optical films 1 to 34 were evaluated as described below. Tables 1 and 2 show the configurations of the optical films and the results of evaluation thereof.

### (Evaluation of Transparency: Measurement of Haze)

The hazes of the optical films 1 to 34 were measured with HAZE METER NDH5000 manufactured by Tokyo Denshoku Co., Ltd. The optical films were evaluated for transparency based on the criteria described below. The optical film of the present invention, which is for use in a light-emitting device, preferably has a haze of less than 1.2%.

1: 5.0% or more

2: 1.2% or more and less than 5.0%

3: 0.9% or more and less than 1.2%

4: 0.7% or more and less than 0.9%

5: 0.5% or more and less than 0.7%

6: 0.3% or more and less than 0.5%

7: 0.2% or more and less than 0.3%

8: 0.15% or more and less than 0.2%

9: 0.1% or more and less than 0.15%

10: less than 0.1%

### (Evaluation of Emission Efficiency)

Each of the optical films 1 to 34 was excited with blue-violet light of 405 nm, and the efficiency of emission of white light having a color temperature of 7,000 K was measured with an emission spectrometric system MCPD-7000 (manufactured by Otsuka Electronics Co., Ltd.). The emission efficiency was evaluated based on the criteria described below (the emission efficiency of the comparative optical film 25 was taken as 100). A larger numerical value indicates a higher emission efficiency.

1: less than 90

2: 90 or more and less than 95

3: 95 or more and less than 103

4: 103 or more and less than 110

5: 110 or more and less than 115

6: 115 or more and less than 120

7: 120 or more and less than 125

8: 125 or more and less than 130

9: 130 or more and less than 135

10: 135 or more

### (Evaluation of Durability)

Each of the optical films 1 to 34 was subjected to an accelerated degradation treatment at 85° C. and 85% RH for 3,500 hours. Thereafter, the emission efficiency of the film was measured as described above, to determine the ratio of the emission efficiency after the accelerated degradation treatment to that before the treatment. The film was evaluated for durability based on the criteria described below. A larger numerical value indicates a higher durability.

1: less than 0.5

2: 0.5 or more and less than 0.6

3: 0.6 or more and less than 0.65

4: 0.65 or more and less than 0.7

5: 0.7 or more and less than 0.75

6: 0.75 or more and less than 0.8

7: 0.8 or more and less than 0.85

8: 0.85 or more and less than 0.9

9: 0.9 or more and less than 0.95

10: 0.95 or more

TABLE 1

| OPTICAL | | SEMICONDUCTOR | | | | | | | |
|---|---|---|---|---|---|---|---|---|---|
| FILM | | NANOPARTICLES | | | | | | | |
| No. | SUBSTRATE | *1 | No. | STRUCTURE | *2 | METAL ALKOXIDE | *3 | *4 | RESIN MATERIAL |
| 1 | PET | 1-1 | A1 | InP/ZnS | — | — | — | NOT DONE | PMMA |
| 2 | PET | 1-2 | A2 | InP/ZnS | TEOS | — | — | DONE | PMMA |
| 3 | PET | 1-3 | A3 | InP/ZnS | TEOS | ALUMINUM TRIISOPROPOXIDE | — | DONE | PMMA |
| 4 | PET | 1-4 | A4 | InP/ZnS | TEOS | COPPER ISOPROPOXIDE | — | DONE | PMMA |
| 5 | PET | 2-1 | B1 | InP/ZnS | — | IRON ISOPROPOXIDE | — | NOT DONE | PMMA |
| 6 | PET | 1-4 | A4 | InP/ZnS | TEOS | COPPER ISOPROPOXIDE | — | DONE | UV-CURABLE RESIN |
| 7 | PET | 2-2 | B2 | InP/ZnS | TEOS | IRON ISOPROPOXIDE | — | DONE | UV-CURABLE RESIN |
| 8 | PET | 3-3 | C3 | CdSe/ZnS | TEOS | IRON ISOPROPOXIDE | — | DONE | UV-CURABLE RESIN |
| 9 | PET | 4-1 | D1 | CdSe/ZnS | TEOS | IRON ISOPROPOXIDE | — | DONE | UV-CURABLE RESIN |
| 10 | PET | 4-2 | D2 | CdSe/ZnS | TEOS | TRIISOPROPYL BORATE | — | DONE | UV-CURABLE RESIN |
| 11 | PET | 4-3 | D3 | CdSe/ZnS | TEOS | MAGNESIUM N-PROPOXIDE | — | DONE | UV-CURABLE RESIN |
| 12 | PET | 4-4 | D4 | CdSe/ZnS | TEOS | TITANIUM | — | DONE | UV-CURABLE RESIN |
| | | | | | | TETRASTEARYLALKOXIDE | | | |
| 13 | PET | 4-5 | D5 | CdSe/ZnS | TEOS | CALCIUM ISOPROPOXIDE | — | DONE | UV-CURABLE RESIN |
| 14 | PET | 4-6 | D6 | CdSe/ZnS | TEOS | ZINC TERT-BUTOXIDE | — | DONE | UV-CURABLE RESIN |
| 15 | PET | 4-7 | D7 | CdSe/ZnS | TEOS | GALLIUM ISOPROPOXIDE | — | DONE | UV-CURABLE RESIN |
| 16 | PET | 4-8 | D8 | CdSe/ZnS | TEOS | ZIRCONIUM ISOPROPOXIDE | — | DONE | UV-CURABLE RESIN |
| 17 | PET | 4-9 | D9 | CdSe/ZnS | TEOS | INDIUM ISOPROPOXIDE | — | DONE | UV-CURABLE RESIN |
| 18 | PET | 1-5 | A9 | InP/ZnS | PHPS | IRON ISOPROPOXIDE | — | DONE | UV-CURABLE RESIN |
| 19 | PET | 1-6 | A6 | InP/ZnS | PHPS | ALUMINUM TRI-N-BUTOXIDE | — | DONE | UV-CURABLE RESIN |

| OPTICAL | | | EVALUATION | | | |
|---|---|---|---|---|---|---|
| FILM | | LAYER | | EMISSION | | |
| No. | *5 | STRUCTURE | TRANSPARENCY | EFFICIENCY | DURABILITY | NOTE |
| 1 | — | SINGLE LAYER | 9 | 2 | 1 | COMPARATIVE |
| 2 | — | SINGLE LAYER | 2 | 3 | 2 | COMPARATIVE |
| 3 | — | SINGLE LAYER | 7 | 6 | 7 | INVENTIVE |
| 4 | — | SINGLE LAYER | 6 | 4 | 4 | INVENTIVE |
| 5 | — | SINGLE LAYER | 10 | 2 | 1 | COMPARATIVE |
| 6 | UV | SINGLE LAYER | 6 | 5 | 6 | INVENTIVE |
| 7 | UV | SINGLE LAYER | 6 | 6 | 7 | INVENTIVE |
| 8 | UV | SINGLE LAYER | 6 | 6 | 6 | INVENTIVE |
| 9 | UV | SINGLE LAYER | 5 | 6 | 6 | INVENTIVE |
| 10 | UV | SINGLE LAYER | 4 | 6 | 7 | INVENTIVE |
| 11 | UV | SINGLE LAYER | 5 | 6 | 6 | INVENTIVE |
| 12 | UV | SINGLE LAYER | 3 | 7 | 6 | INVENTIVE |
| 13 | UV | SINGLE LAYER | 4 | 6 | 5 | INVENTIVE |
| 14 | UV | SINGLE LAYER | 4 | 6 | 5 | INVENTIVE |
| 15 | UV | SINGLE LAYER | 4 | 6 | 5 | INVENTIVE |
| 16 | UV | SINGLE LAYER | 4 | 6 | 5 | INVENTIVE |
| 17 | UV | SINGLE LAYER | 4 | 6 | 5 | INVENTIVE |
| 18 | UV | SINGLE LAYER | 8 | 7 | 7 | INVENTIVE |
| 19 | UV | SINGLE LAYER | 8 | 8 | 8 | INVENTIVE |

*1: SYNTHETIC PROCESS
*2: SILICON COMPOUND
*3: MODIFICATION
*4: SILICA COATING OF SEMICONDUCTOR NANOPARTICLES
*5: POST-TREATMENT OF FILM

TABLE 2

| OPTICAL | | SEMICONDUCTOR | | | | | | |
|---|---|---|---|---|---|---|---|---|
| FILM | | NANOPARTICLES | | | | | | |
| No. | SUBSTRATE | *1 | No. | STRUCTURE | *2 | METAL ALKOXIDE | MODIFICATION | *3 |
| 20 | PET | 1-7 | A7 | InP/ZnS | PHPS | TRIDODECYLOXYALUMINUM | HEATING | DONE |
| 21 | PET | 1-9 | A9 | InP/ZnS | PHPS | ALUMINUM | EXCIMER LASER | DONE |
| | | | | | | ETHYLACETOACETATE | BEAM | |
| | | | | | | DIISOPROPYLATE | | |
| 22 | PET | 1-10 | A10 | InP/ZnS | PHPS | ALUMINUM DIISOPROPYLATE | EXCIMER LASER | DONE |
| | | | | | | MONO-SEC-BUTYLATE | BEAM | |
| 23 | PET | 1-11 | A11 | InP/ZnS | PHPS | TRIDODECYLOXYALUMINUM | EXCIMER LASER | DONE |
| | | | | | | | BEAM | |
| 24 | PET | 3-4 | C4 | CdSe/ZnS | PHPS | IRON ISOPROPOXIDE | — | DONE |
| 25 | PET | 3-2 | C2 | CdSe/ZnS | TEOS | — | — | DONE |
| 26 | PET | 1-8 | A8 | InP/ZnS | PHPS | ALUMINUM TRI-N-BUTOXIDE | EXCIMER LASER | DONE |
| | | | | | | | BEAM | |
| 27 | PET | 3-1 | C1 | CdSe/ZnS | HSQ | COPPER ISOPROPOXIDE | — | NOT |
| | | | | | | | | DONE |
| 28 | PET | 3-1 | C1 | CdSe/ZnS | HSQ | COPPER ISOPROPOXIDE | EXCIMER LASER | NOT |
| | | | | | | | BEAM | DONE |
| 29 | PET | 3-1 | C1 | CdSe/ZnS | HSQ | — | EXCIMER LASER | NOT |
| | | | | | | | BEAM | DONE |
| 30 | PET | 1-1 | A1 | InP/ZnS | HSQ | COPPER ISOPROPOXIDE | EXCIMER LASER | NOT |
| | | | | | | | BEAM | DONE |
| 31 | PET | 3-1 | C1 | CdSe/ZnS | PHPS | COPPER ISOPROPOXIDE | EXCIMER LASER | NOT |
| | | | | | | | BEAM | DONE |
| 32 | PC | 1-8 | A8 | InP/ZnS | PHPS | ALUMINUM TRI-N-BUTOXIDE | EXCIMER LASER | DONE |
| | | | | | | | BEAM | |
| 33 | TAC | 1-8 | A8 | InP/ZnS | PHPS | ALUMINUM TRI-N-BUTOXIDE | EXCIMER LASER | DONE |
| | | | | | | | BEAM | |
| 34 | PET | 1-10 | A10 | InP/ZnS | PHPS | ALUMINUM DIISOPROPYLATE | EXCIMER LASER | DONE |
| | | | | | | MONO-SEC-BUTYLATE | BEAM | |

| OPTICAL | | | | | | | |
|---|---|---|---|---|---|---|---|
| FILM | | | LAYER | EVALUATION | | | |
| No. | RESIN MATERIAL | *4 | STRUCTURE | TRANSPARENCY | *5 | DURABILITY | NOTE |
| 20 | UV-CURABLE RESIN | UV | SINGLE LAYER | 8 | 10 | 10 | INVENTIVE |
| 21 | UV-CURABLE RESIN | UV | SINGLE LAYER | 8 | 10 | 9 | INVENTIVE |
| 22 | UV-CURABLE RESIN | UV | SINGLE LAYER | 8 | 9 | 10 | INVENTIVE |
| 23 | UV-CURABLE RESIN | UV | SINGLE LAYER | 8 | 10 | 10 | INVENTIVE |
| 24 | UV-CURABLE RESIN | UV | SINGLE LAYER | 7 | 7 | 7 | INVENTIVE |
| 25 | UV-CURABLE RESIN | UV | SINGLE LAYER | 1 | 3 | 3 | COMPARATIVE |
| 26 | UV-CURABLE RESIN | UV + | SINGLE LAYER | 8 | 9 | 9 | INVENTIVE |
| | | VUV | | | | | |
| 27 | — | — | SINGLE LAYER | 5 | 4 | 3 | INVENTIVE |
| 28 | — | VUV | SINGLE LAYER | 6 | 4 | 4 | INVENTIVE |
| 29 | — | VUV | SINGLE LAYER | 2 | 1 | 1 | COMPARATIVE |
| 30 | — | VUV | SINGLE LAYER | 7 | 4 | 4 | INVENTIVE |
| 31 | — | VUV | SINGLE LAYER | 7 | 5 | 5 | INVENTIVE |
| 32 | UV-CURABLE RESIN | UV | SINGLE LAYER | 8 | 9 | 8 | INVENTIVE |
| 33 | UV-CURABLE RESIN | UV | SINGLE LAYER | 8 | 7 | 9 | INVENTIVE |
| 34 | UV-CURABLE RESIN | UV | TWO LAYER | 8 | 10 | 10 | INVENTIVE |

*1: SYNTHETIC PROCESS
*2: SILICON COMPOUND
*3: SILICA COATING OF SEMICONDUCTOR NANOPARTICLES
*4: POST-TREATMENT OF FILM
*5: EMISSION EFFICIENCY

The results shown in Tables 1 and 2 indicate that the luminous material of the present invention, which contains semiconductor nanoparticles, a metal alkoxide, and a silicon compound, exhibits transparency, emission efficiency, and durability higher than those of the comparative luminous material.

The results also indicate that these properties are further improved when the silicon-containing compound is a polysilazane or a modified polysilazane, the silicon-containing compound is modified, and the luminous material is produced by the aforementioned process B.

### Example 2

### Production of Light-Emitting Device

Each of the optical films 1 to 34 formed in Example 1 (corresponding to an optical film 4 in FIG. 1) was attached to a light emission surface 5a of a light guide 5 as shown in FIG. 1, to produce a light-emitting device.

<<Evaluation of Light-Emitting Device>>

The resultant light-emitting device was caused to emit light at 85° C. and 85% RH for 3,000 hours, and then the emission efficiency thereof was measured. The results indicated that the light-emitting device including the optical film of the present invention undergoes a smaller change in emission efficiency than the comparative light-emitting device; i.e., the light-emitting device of the present invention exhibits high durability.

### INDUSTRIAL APPLICABILITY

The luminous material of the present invention contains semiconductor nanoparticles, a metal alkoxide, and a silicon compound. The luminous material has high transparency and high durability such that the semiconductor nanoparticles are prevented from being degraded by oxygen for a long period of time. The luminous material can be used in an optical film that is suitable for use in a light-emitting device, such as a display.

### EXPLANATION OF REFERENCE NUMERALS

1: display
2: image display panel
3: primary light source
4: optical film
5: light guide
5a: light emission surface
5b: side face
6: color filter unit
7: image display layer

1. A luminous material comprising:
a semiconductor nanoparticle;
a metal alkoxide; and
a silicon compound.

2. The luminous material according to claim 1, wherein metal of the metal alkoxide comprises at least one of boron (B), magnesium (Mg), aluminum (Al), calcium (Ca), titanium (Ti), iron (Fe), zinc (Zn), gallium (Ga), zirconium (Zr), indium (In) and rhodium (Rh).

3. The luminous material according to claim 1, wherein the silicon compound is at least one of a polysilazane and a modified polysilazane.

4. The luminous material according to claim 1, wherein the semiconductor nanoparticle is coated with the silicon compound.

5. The luminous material according to claim 1, wherein the silicon compound is modified.

6. A method for producing the luminous material according to claim 1, comprising:
preparing a mixture of the metal alkoxide and the silicon compound; and
reacting the mixture with the semiconductor nanoparticle, to coat the semiconductor nanoparticle with silica.

7. An optical film comprising a semiconductor nanoparticulate layer comprising the luminous material according to claim 1.

8. A light-emitting device comprising the optical film according to claim 7.
